(19) United States
(12) Patent Application Publication
(10) Pub. No.: US 2025/0374673 A1
(43) Pub. Date: Dec. 4, 2025

(54) SINGLE-DIE GALVANIC ISOLATION USING SILICON-ON-INSULATOR AND DEEP TRENCHES

(71) Applicant: SEMICONDUCTOR COMPONENTS INDUSTRIES, LLC, Scottsdale, AZ (US)

(72) Inventors: Jeffrey Peter GAMBINO, Gresham, OR (US); Bruce Blair GREENWOOD, Gresham, OR (US)

(73) Assignee: SEMICONDUCTOR COMPONENTS INDUSTRIES, LLC, Scottsdale, AZ (US)

(21) Appl. No.: 18/680,633

(22) Filed: May 31, 2024

(51) Int. Cl. H01L 27/12; H01L 21/768; H01L 21/84; H01L 23/48; H01L 23/522

(52) U.S. Cl. CPC H10D 86/201; H01L 21/76251; H01L 21/76898; H01L 23/481; H01L 23/5223; H01L 23/5227; H10D 86/01

(57) ABSTRACT

A semiconductor die includes a silicon layer. A first device circuit is formed in a first region at a first end of the silicon layer, and a second device circuit is formed in a second region at a second end of a silicon layer at a distance from the first region. The first end is opposite the second end, and the first device circuit is galvanically isolated from the second device circuit.

### TECHNICAL FIELD

This description relates to galvanic isolation of electrical and electronic circuits.

### BACKGROUND

Galvanic isolation is a technique used to prevent unwanted direct current flow between different parts of an electrical system while still allowing signal and power transfer. Galvanic isolation is needed for three main reasons: safety, ground loop prevention, and noise immunity. Galvanic isolation can protect people and equipment from electrical shock, eliminate ground loops that can cause interference in audio and video systems, and reduce the effects of electromagnetic interference (EMI) on sensitive electronic components. There are different techniques for galvanic isolation for power and signal transfer. The different techniques of galvanic isolation can be implemented using circuits or devices such as a transformer, a capacitor, an optical coupler, and a Hall effect sensor. For example, transformers are commonly used for power isolation, while opto-isolators are popular for signal isolation. These techniques for galvanic isolation (e.g., opto-couplers, digital isolators (DI), Digi-mas (DM), etc.) are commonly implemented to isolate two individual circuits fabricated on two different semiconductor dies or chips (in other words, when each of the two individual circuits is fabricated on a respective semiconductor die or chip).

### SUMMARY

In a general aspect, a semiconductor die includes a silicon layer. A first device circuit is formed in a first region at a first end of the silicon layer, and a second device circuit is formed in a second region at a second end of a silicon layer at a distance from the first region. The first end is opposite the second end, and the first device circuit is galvanically isolated from the second device circuit.

In a general aspect, a semiconductor die includes a silicon layer and a handle substrate. A first device circuit is formed in the silicon layer in a first region at a first end of the semiconductor die. A second device circuit is formed in the handle substrate in a second region at a second end of the semiconductor die. A plurality of dielectric layers is disposed between the handle substrate and the silicon layer, and the first device circuit in the silicon layer is galvanically isolated from the second device circuit formed in the handle substrate by the plurality of dielectric layers coupling the handle substrate and the silicon layer.

In a general aspect, a semiconductor die includes three sections of a three-phase inverter circuit including a first phase section, a second phase section, and a third phase section. The three sections extend parallel to each other in a first direction in the semiconductor die and have a width in a second direction. Each of the three sections includes a low voltage switch at one end of the semiconductor die and a high voltage switch at an opposite end of the semiconductor die. In each phase section, at least one dielectric-filled deep isolation trench extends in the second direction between the low voltage switch and the high voltage switch. Further, for each pair of adjacent phase sections, at least one dielectric-filled deep isolation trench extends in the first direction between each pair of the adjacent phase sections.

In a general aspect, a method includes forming a low voltage device circuit and a high voltage device circuit on a silicon-on-insulator (SOI) wafer. The method further includes disposing a plurality of dielectric layers on top of a silicon overlayer in the SOI wafer, and etching at least one dielectric-filled deep trench in a space between the low voltage device circuit and the high voltage device circuit.

In a general aspect, a method includes forming a low voltage device circuit and a high voltage device circuit on a silicon-on-insulator (SOI) wafer, disposing a plurality of dielectric layers on top of a silicon overlayer in the SOI wafer, coupling a handle substrate to the SOI wafer and, removing a silicon substrate in the SOI wafer coupled to the handle substrate. The method further includes etching, from an exposed surface of a buried oxide layer, at least one dielectric-filled deep trench in a space between the low voltage device circuit and the high voltage device circuit, depositing a silicon nitride layer on an exposed surface of a buried-oxide layer of the SOI wafer, etching a through-substrate via (TSV) from a backside of the SOI wafer through the silicon nitride layer to access a metal level in the SOI wafer, and lining the TSV with a conductive material.

In a general aspect, a method includes forming a first device circuit on a handle substrate and forming a first redistribution layer including a plurality of metal levels. Each metal level is included in a respective intermetal dielectric layer on the handle substrate. The method further includes embedding at least one first planarized metal pad in a topmost intermetal dielectric layer on the handle substrate, forming a second device circuit on a silicon-on-insulator (SOI) wafer and forming a second redistribution layer including a plurality of metal levels. Each metal level is included in a respective intermetal dielectric layer on the SOI wafer.

The method further includes embedding at least one second planarized metal pad in a topmost intermetal dielectric layer on the SOI wafer, coupling the handle substrate to the SOI wafer, and removing a silicon substrate in the SOI wafer coupled to the handle substrate.

The method further includes etching, from an exposed surface of a buried oxide layer of the SOI wafer, at least one dielectric-filled deep trench in a space between the first device circuit and the second device circuit;

The method further includes etching a through substrate via (TSV) from a backside of the SOI wafer though a silicon overlayer and any intervening dielectric layers to access a metal level in the second redistribution layer on the SOI wafer, and lining the TSV with a conductive material.

The details of one or more implementations are set forth in the accompanying drawings and the description below. Other features will be apparent from the description and drawings, and from the claims.

### BRIEF DESCRIPTION OF THE DRAWINGS

FIG. 1A illustrates a plan view of a semiconductor die including two galvanically isolated device circuits, in accordance with the principles of the present disclosure.

FIG. 1B and FIG. 1C illustrate cross-sectional views of the semiconductor die of FIG. 1A, in accordance with the principles of the present disclosure.

FIG. 2 illustrates a cross-sectional view of an example semiconductor die containing the two galvanically isolated circuits that are initially fabricated on two different device wafers, in accordance with the principles of the present disclosure.

FIG. 3 illustrates an example method for fabricating a single semiconductor die including two circuits that are galvanically isolated from each other, in accordance with the principles of the present disclosure.

FIGS. 4A through 4I illustrate plan views or cross-sectional views of semiconductor wafers being processed through multiple steps of a semiconductor die fabrication process according to the method of FIG. 3.

FIG. 5 illustrates another example method for fabricating a single semiconductor die including two circuits that are galvanically isolated from each other, in accordance with the principles of the present disclosure.

FIGS. 6A through 6J illustrate plan views or cross-sectional views of semiconductor wafers being processed through multiple steps of a semiconductor die fabrication process according to the method of FIG. 5, in accordance with the principles of the present disclosure.

FIG. 7 illustrates another example method for making a single semiconductor die including two circuits that are mutually galvanically isolated, in accordance with the principles of the present disclosure.

FIG. 8 is a plan view of an example three-phase inverter circuit fabricated on a single die.

### DETAILED DESCRIPTION

Galvanic isolation is a technique used to isolate functional sections of electrical systems to prevent current flow; no direct conduction path between two isolated functional sections is permitted.

Example galvanic isolators between two electronic circuits are described herein. In example implementations, the two electronic circuits may be fabricated in a single semiconductor die. An example galvanic isolator blocks flow of direct current between the two electronic circuits fabricated in a single semiconductor die. Energy or information can still be exchanged between the two electronic circuits such as by capacitive or inductive coupling.

In example implementations, galvanic isolators are constructed between two electronic circuits in the single semiconductor die using isolating semiconductor device structures such as dielectric-filled deep trench isolation (DTI) and silicon-on-insulator (SOI) structures, in accordance with the principles of the present disclosure.

The single semiconductor die with the two galvanically isolated electronic circuits fabricated in it may be made of semiconductor material such as silicon (Si), silicon-germanium (SiGe), gallium arsenide (GaAs), gallium nitride (GaN), silicon carbide (SiC), etc. One or more of the semiconductor devices (e.g., single semiconductor die as described herein) die may be disposed on, or coupled to, a direct bonded copper (DBC) substrate (e.g., a direct bonded metal (DBM) substrate) in a semiconductor device package. The DBC can include an insulating layer (e.g., a ceramic) disposed between metal layers. One or more of the metal layers can include, for example, traces for electrical communications and/or can be used for heat dissipation.

The semiconductor devices (e.g., single semiconductor die) described herein may, for example, be soldered or sintered to the DBC substrate. The semiconductor devices described herein may, for example, be soldered or sintered to, for example, a leadframe,

In some instances, a single semiconductor die made of one type of semiconductor material (e.g. Si) and another single semiconductor die made of a second type of semiconductor material (e.g., SiC). The multiple single semiconductor die made of different semiconductor materials may be packaged together in, for example, a hybrid semiconductor device package or system.

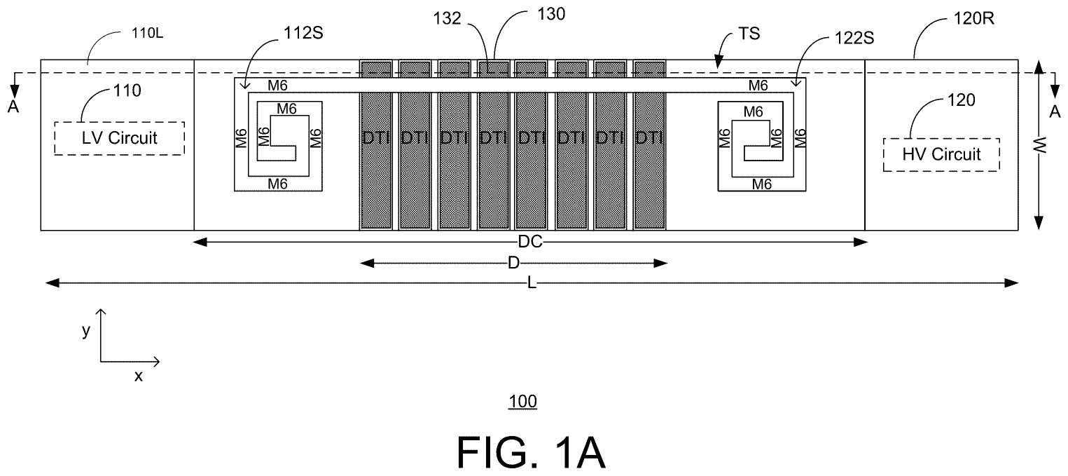

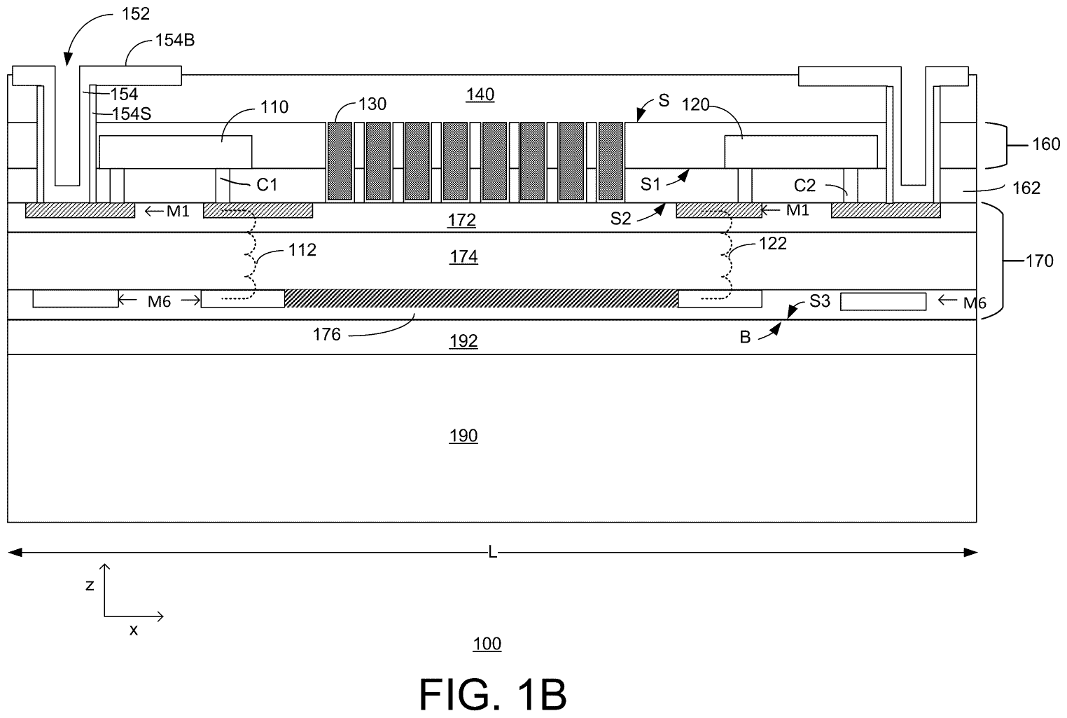

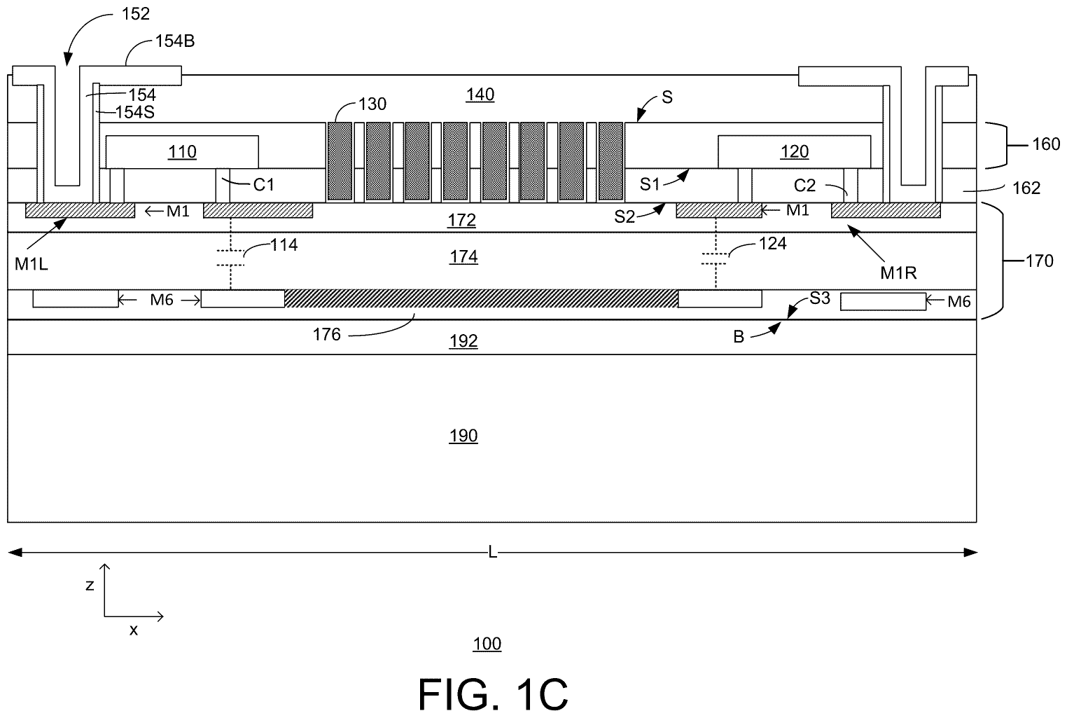

FIG. 1A illustrates a plan view and FIG. 1B and FIG. 1C illustrate cross-sectional views of a semiconductor die 100. Semiconductor die 100 may include a low voltage device circuit 110 and a high voltage device circuit 120 that are galvanically isolated from each other.

Semiconductor die 100 may, for example, have a rectangular shape with a length L and a width W. The two electronic circuits (e.g., a low voltage device circuit 110, and a high voltage device circuit 120) may be fabricated in a left side end region 110L and a right side end region 120R of the die, respectively. The two circuits are galvanically isolated from each other so that no direct current circulation can take place between the two circuits. However, the two circuits are inductively (or capacitively) coupled to allow an exchange of AC signals between the two circuits. In example implementations, the low voltage device circuit 110 and the high voltage device circuit 120 may be fabricated in a single device wafer. A redistribution layer including one or more levels of metallization (wiring) may be formed on the device wafer to provide I/O access to the device circuits. The device wafer after metallization (i.e., with the redistribution layer formed on it) may be bonded face down to a handle substrate. An oxide or dielectric layer may be disposed on a surface of the handle substrate to which the device wafer is bonded. The metallization of the device wafer may include several metal levels (e.g., metal level M1, M2, M3, M4, M5, M6, and M7) that can provide inductive or capacitive coupling for passage of AC signals between low voltage device circuit 110 and the high voltage device circuit 120. Semiconductor die 100 may be formed by singulation of the bonded pair of the device wafer and the handle substrate.

FIG. 1A schematically shows a plan view of a section of the semiconductor die having a length L (in the x direction) and a width W (in the y direction). An end region 110L on one side of semiconductor die 100 may include the low voltage device circuit 110 and an end region 120R on an opposite side of semiconductor die 100 along length L may include the high voltage device circuit 120. The two circuits may be separated by a distance (e.g., distance DC) in the x direction along a top surface of the semiconductor die. Low voltage device circuit 110 and high voltage device circuit 120 may be galvanically isolated from each other (in the x direction) by a plurality of dielectric-filled deep isolation trenches (e.g., DTI trench 130) disposed over a distance D between end region 110L containing low voltage device circuit 110 and end region 120R containing high voltage device circuit 120. The DTI trench 130 may be filled with insulating material 132 (e.g., silicon oxide, or silicon nitride, etc.). In example implementations, a number of the trenches disposed over the distance D may be a number between 1 and 10 (e.g., n=8). In example implementations, the distance D may be number between 4 μm and 14 μm (e.g., 8 μm)

In semiconductor die 100, the several metal levels (e.g., metal level M1, M2, M3, M4, M5, and M6, FIG. 1B) in the redistribution layers of the device wafer may be capacitively or inductively coupled forming capacitors or inductors. For example, first metal level M1 may be inductively coupled to a higher metal level embedded in a higher or outermost IMD layer to provide an AC signal path between the first device circuit and the second device circuit.

In some implementations, metal level M1 may, for example, be inductively coupled to metal level 6 to form inductors 112 and 122 (as shown, for example, in FIG. 1B). In some implementations, metal level M1 may, for example, be capacitively coupled to metal level 6 to form capacitors 114 and 124 (as shown, for example, in FIG. 1C). These capacitors or inductors may allow passage of AC signals between low voltage device circuit 110 and the high voltage device circuit 120. In FIG. 1A, inductors 112 and 122 are represented by spirals 112S and 122S that are formed by metal level M6 on a top surface TS of the die next to low voltage device circuit 110 and high voltage device circuit 120, respectively.

In example implementation, metal level M1 of inductor 112 may be connected to low voltage device circuit 110 by a conductor C1 and metal level M1 of inductor 122 may be connected to high voltage device circuit 120 by a conductor C2. The two inductors may be inductively coupled to allow transmission of AC signals between the galvanically-isolated low voltage device circuit 110 and high voltage device circuit 120.

FIG. 1B shows a cross-sectional view (in the z-x plane) of semiconductor die 100 along line A-A in FIG. 1A.

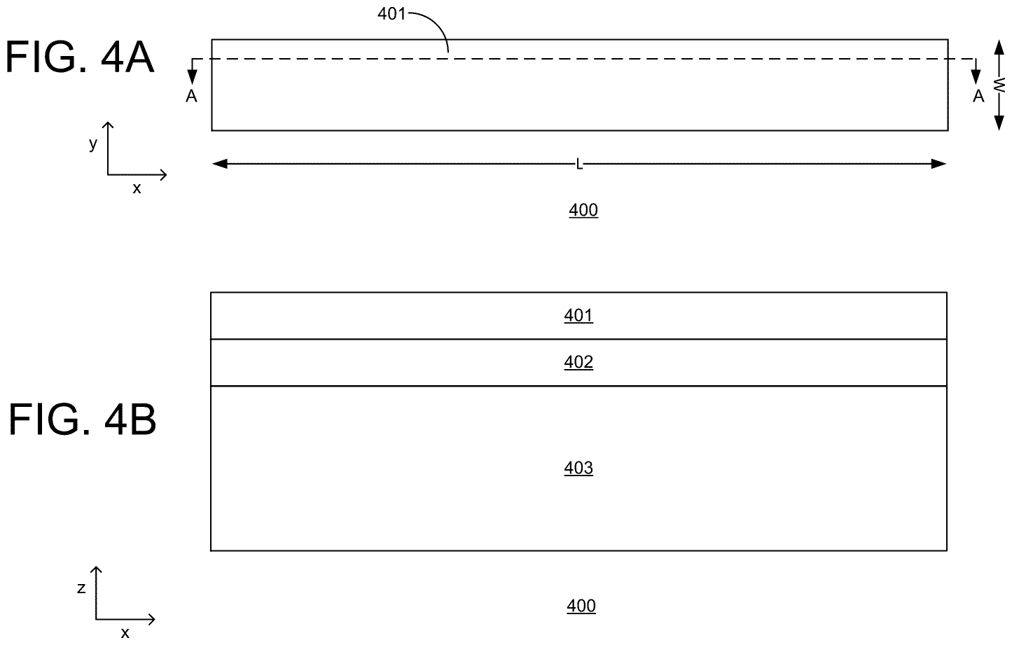

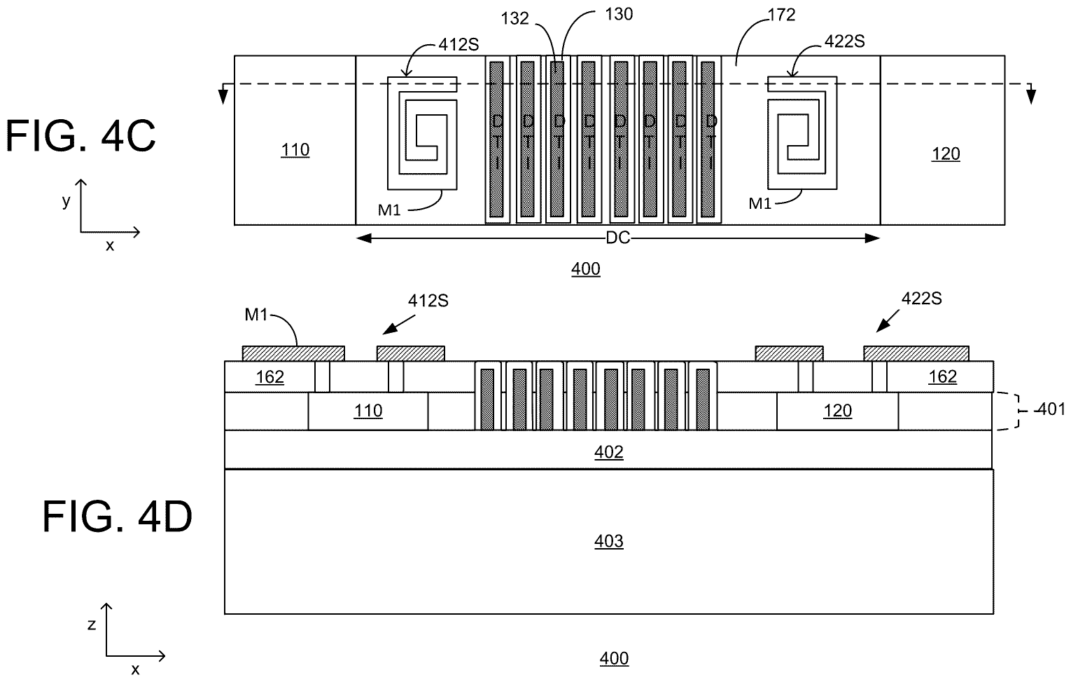

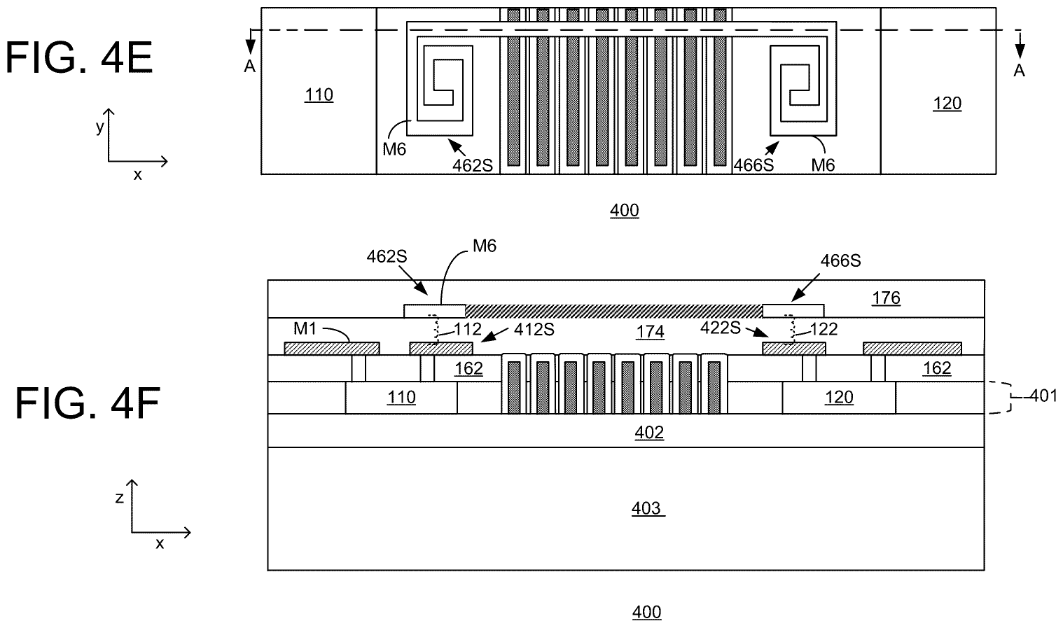

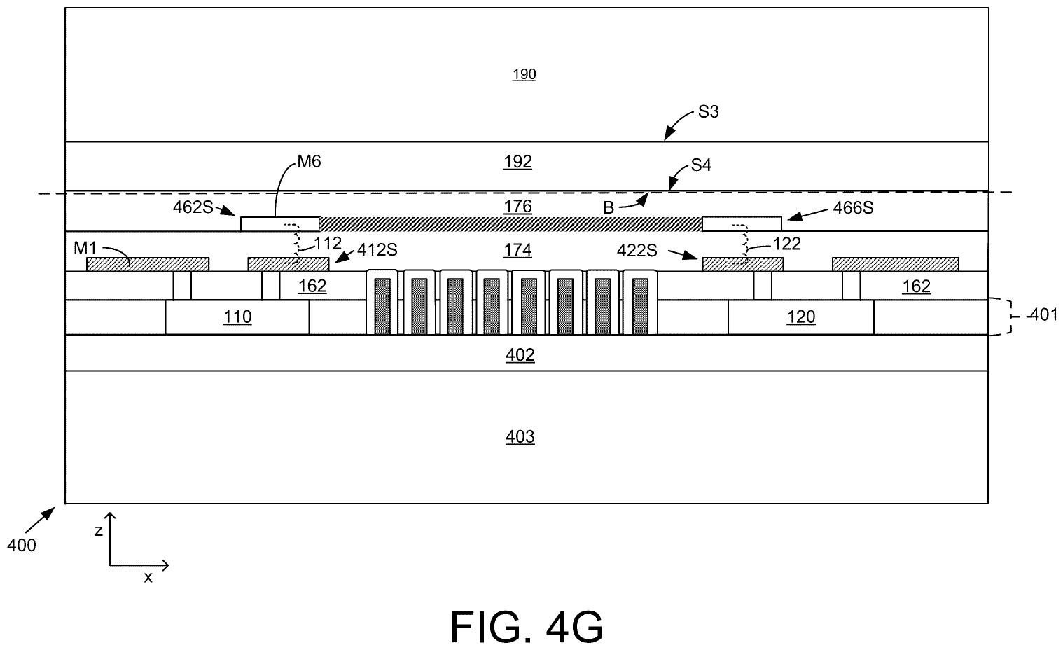

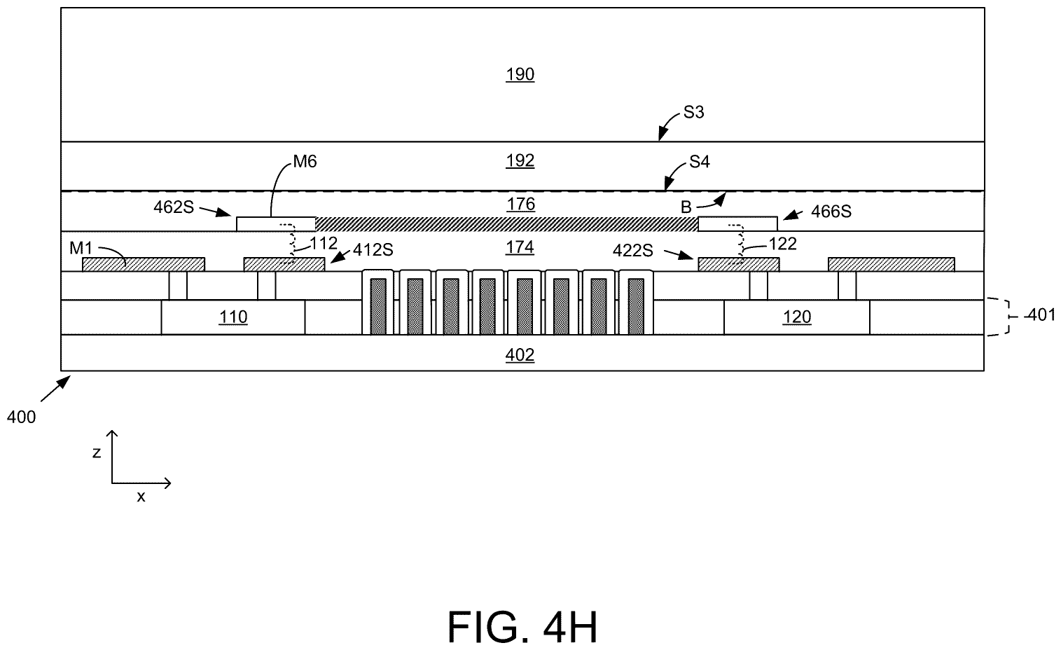

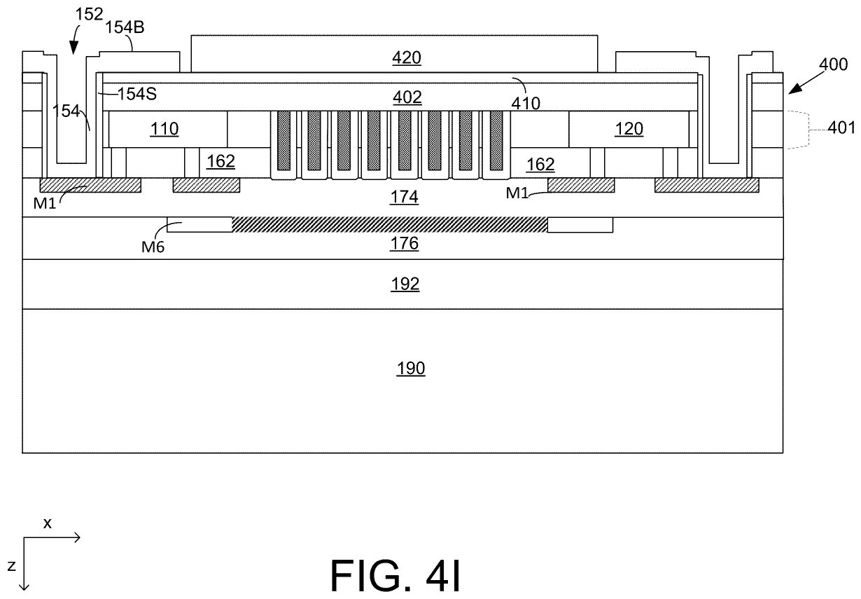

As shown in FIG. 1B, an ILD layer 192 is disposed on handle substrate 190. In example implementations, handle substrate 190 may be a silicon wafer, and ILD layer 192 may be a silicon oxide layer. Handle substrate 190 and ILD layer 192 may respectively correspond to the silicon overlayer and the buried oxide layer of silicon-on-insulator wafer (e.g., a SOI wafer, FIG. 4A and 4B)

Further, as shown in FIG. 1B, low voltage device circuit 110 and high voltage device circuit 120 may be fabricated in a device wafer 160. Device wafer 160 is shown face down (i.e., upside down) toward the bottom of the page in FIG. 1B. An interlayer dielectric layer (e.g., ILD layer 162) is disposed on a top surface S1 of device wafer 160. Dielectric-filled deep trenches (e.g., DTI trench 130) extend from a top surface S2 of ILD layer 162 through device wafer 160 to a back surface S of device wafer 160 to galvanically isolate low voltage device circuit 110 and high voltage device circuit 120 in the x direction.

A redistribution layer (e.g., RDL 170) for device wafer 160 is disposed on back surface S2 of ILD layer 162. RDL 170 may be a multi-metal levels redistribution layer. In other words, RDL 170 can include a plurality of metal levels. Each of the plurality of metal levels is embedded in, or disposed on, a respective intermetallic dielectric (IMD) layer. The plurality of metal levels includes a first metal level with a first portion connected to the first device circuit and a second disconnected portion connected to the second device circuit.

RDL 170 may include several metal levels (e.g., metal level M1, . . . . M6) for input/output connections to, and for interconnecting, elements of low voltage device circuit 110 and high voltage device circuit 120. For visual clarity, metal levels M2-M5 are omitted and only metal level M1 and metal level M6 are shown in FIG. 1B. The metal levels may be disposed in intermetal dielectric layers (IMD layers). For example, metal level M1 may be disposed in an IMD layer 172; metal levels M2-M5 (not shown) may be disposed in an IMD layer 174; metal level M6 may be disposed in an IMD layer 176. In example implementations, the intermetal dielectric layers (e.g., IMD layer 172, IMD layer 174, IMD layer 176, etc.) may be silicon oxide layers. In example implementations, a total thickness of the IMD layers (e.g., IMD layer 172 to IMD layer 176 may be in a range 4 μm to 8 μm (e.g., 4.7 μm).

In example implementation, the plurality of metal levels includes a first metal level (M1) with a first portion (M1L) connected to the first device circuit and a second portion (M1R) connected to the second device circuit. The first portion M1L of M1 may be disconnected from second portion M1R.

Further, as shown in FIG. 1B, after metallization, device wafer 160 is placed face down so that a top surface S3 of IMD layer 176 is in contact with ILD layer 192 disposed on handle substrate 190. Device wafer 160 may be bonded to handle substrate 190, for example, by an oxide-oxide bond formed along interface B between IMD layer 176 and ILD layer 192 disposed on handle substrate 190.

Further, as shown in FIG. 1B, a passivating dielectric layer 140 may be disposed on the back surface S of device wafer 160 (now corresponding to a top surface of semiconductor die 100 as shown in FIG. 1B). Passivating dielectric layer 140 may, for example, be a layer of silicon oxide. In example implementations, electrical connection to metal level M1 of the circuits (e.g., low voltage device circuit 110, high voltage device circuit 120) can be made by an arrangement of metal-lined through-substrate vias (TSV). FIG. 1B shows for example, a TSV 152 extending from a top surface TS of passivating dielectric layer 140 through device wafer 160 and through ILD layer 162 to expose metal level M1 in IMD layer 172. A metal liner 154 disposed in TSV 152 may connect metal level M1 to a bond pad 154B formed on the top surface of passivating dielectric layer 140. An insulating spacer 154S may be disposed along the walls of the TSV prior to the TSV metallization to isolate the TSV from the substrate material (e.g., Si device wafer 160). Insulating spacer layer 154S may be made of silicon oxide or silicon nitride.

In addition to the DC current blocking behavior of DTI trench 130 disposed between low voltage device circuit 110 and high voltage device circuit 120, the several interlayer dielectrics (e.g., passivating dielectric layer 140, ILD layer 162, and ILD layer 192), and the intermetal dielectrics layers (e.g., IMD layer 172, IMD layer 174, IMD layer 176, etc.) in semiconductor die 100 have DC current blocking characteristics that help galvanically isolate low voltage device circuit 110 from high voltage device circuit 120.

In the implementations shown in FIG. 1A and 1B, semiconductor die 100 includes low voltage device circuit 110 and the high voltage device circuit 120 that are initially fabricated in a same device wafer (e.g., device wafer 160). In another example implementation of the galvanic isolation between two electronic circuits in a single semiconductor die, the low voltage device circuit 110 and the high voltage device circuit 120 may be initially fabricated in two separate wafers that are then bonded face-to-face after metallization. The bonded pair of the wafers are then singulated to obtain the single semiconductor die containing the two galvanically isolated circuits (e.g., the low voltage device circuit 110 and the high voltage device circuit 120).

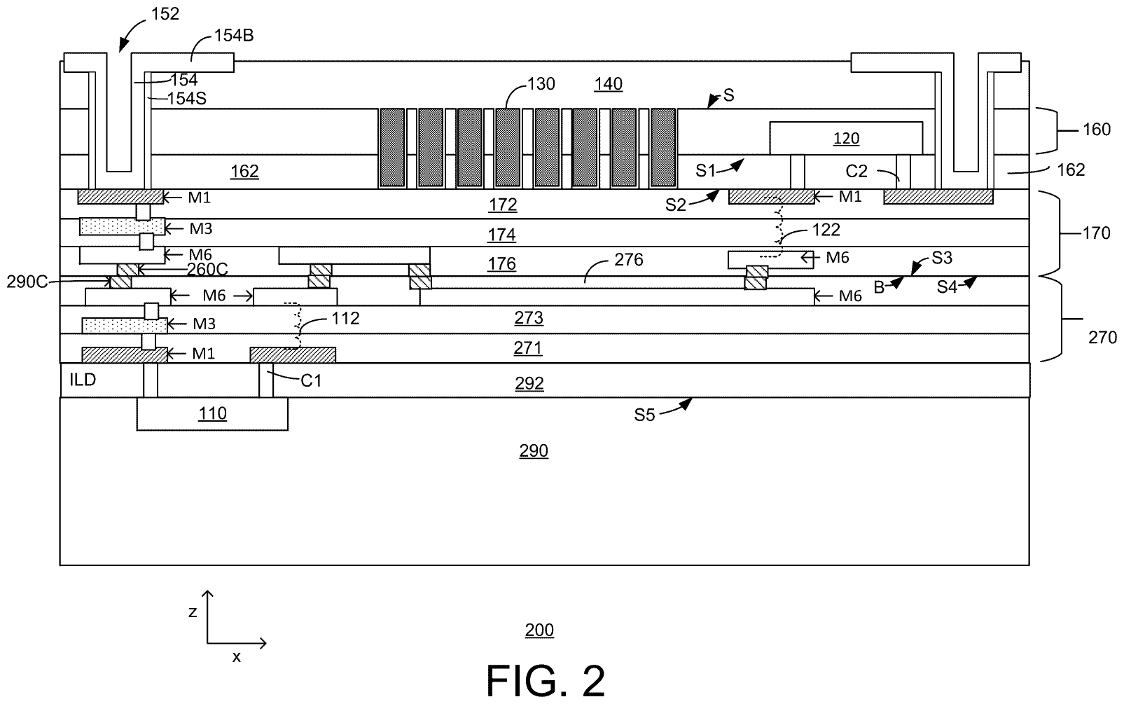

FIG. 2 shows a cross-sectional view of an example semiconductor die 200 containing two galvanically isolated circuits (e.g., the low voltage device circuit 110 and the high voltage device circuit 120) that are initially fabricated on two different device wafers.

As shown in FIG. 2, low voltage device circuit 110 may be fabricated on a handle substrate 290. In example implementations, handle substrate 290 may be a silicon wafer. An interlayer dielectric layer (e.g., IDL 292) may be disposed on a top surface S4 of handle substrate 290 before a redistribution layer (RDL 270) is formed for low voltage device circuit 110 in handle substrate 290. RDL 270 may include several metal levels disposed on IDL 292. RDL 270 of the handle substrate for I/O connections to low voltage device circuit 110 may include several metal levels (e.g., metal level M1, M2, M3, M4, M5 and M6, etc.) that are embedded in respective intermetal dielectric layers (e.g., IMD layer 271, IMD layer 273, IMD layer 276, etc.). For visual clarity, metal levels M2, M4 and M5 are omitted and only metal level M1, metal level M3, and metal level M6 are shown in FIG. 2. The metal levels may be disposed in intermetal dielectric layers (IMD layers). For example, metal level Ml may be disposed in an IMD layer 271; metal level M3 may be disposed in an IMD layer 273, and metal level M6 may be disposed in an IMD layer 276. In example implementations, the intermetal dielectric layers (e.g., IMD layer 271, IMD layer 273, IMD layer 276, etc.) may be silicon oxide layers. In example implementations, a total thickness of the IMD layers (e.g., IMD layer 271 to IMD layer 276 may be in a range 4 μm to 8 μm (e.g., 4.7 μm).

A planarized copper pad 290C may be embedded in a top surface S4 of IMD layer 276. Planarized copper pad 290C may be connected to metal level M6 in RDL 270.

As further shown in FIG. 2, high voltage device circuit 120 may be fabricated on device wafer 160 (as also shown in FIG. 1B). Device wafer 160 is shown face down (i.e. upside down) toward the bottom of the page in FIG. 2. An interlayer dielectric layer (e.g., ILD layer 162) is disposed on a top surface S1 of device wafer 160. A plurality of dielectric-filled deep trenches (e.g., DTI trench 130) extend from a top surface S2 of ILD layer 162 through device wafer 160 to a back surface S of device wafer 160.

Furthermore, a redistribution layer (RDL) 170 for device wafer 160 device wafer 160 is disposed on back surface S2 of ILD layer 162. RDL 170 may include several metal levels (e.g., metal level M1, M2, M3, M4, M5 and M6, etc.). For visual clarity, metal levels M2, M4 and M5 are omitted and only metal level M1, metal level M3, and metal level M6 are shown in FIG. 2. The metal levels of RDL 170 may be disposed in intermetal dielectric layers. For example, metal level M1 may be disposed in IMD layer 172; metal level M3 may be disposed in IMD layer 174; and metal level M6 may be disposed in IMD layer 176.

A planarized copper pad 260C may be embedded in a top surface S4 of IMD layer 276. Planarized copper pad 260C may be connected to metal level M6 in RDL 170.

Metal level M1 may, for example, be inductively coupled to metal level 6 to form inductors 112 and 122 (as shown, for example, in FIG. 2). These capacitors or inductors may allow passage of AC signals between low voltage device circuit 110 and the high voltage device circuit 120.

The plurality of dielectric-filled deep trenches (e.g., DTI trench 130) and galvanically isolate low voltage device circuit 110 and high voltage device circuit 120 in the x direction. A RDL 170 of device wafer 160 is disposed on back surface S2 of ILD layer 162. RDL 170 may include several metal levels (e.g., metal level M1, M2, M3, M4, M5 and M6, etc.). For visual clarity, metal levels M2-M5 are omitted and only metal levels M1 and metal level M6 are shown in FIG. 2. The metal levels of RDL 170 may be disposed in intermetal dielectric layers. For example, metal level M1 may be disposed in IMD layer 172; metal levels M2-M5 (not shown) may be disposed in IMD layer 174; and metal level M6 may be disposed in or on IMD layer 176.

A planarized copper pad 260C may be embedded in a top surface S3 of IMD layer 176.

Further, as shown in FIG. 2, after forming the redistribution layer, device wafer 160 is placed face down on handle substrate 290 so that a top surface S4 of IMD layer 276 is in contact with a top surface S3 of IMD layer 176 with planarized copper pad 290C (in IMD layer 276) aligned with and in contact with planarized copper pad 260° C. (in IMD layer 176). Device wafer 160 may be bonded to handle substrate 290, for example, by a hybrid bond (including an oxide-oxide bond and a copper-copper bond) formed along interface B between IMD layer 176 disposed on device wafer 160 and IMD layer 276 disposed on handle substrate 290.

Semiconductor die 200 may be formed by singulation of the bonded pair of device wafer 160 and handle substrate 290.

In RDL 270, metal level M1 may, for example, be coupled capacitively or inductively to metal level 6 to form, for example, inductor 112, and in RDL 170, metal level M1 may, for example, be coupled capacitively or inductively to metal level 6 to form, for example, inductor 122 (as shown, for example, in FIG. 2). These capacitors or inductors may allow passage of AC signals between low voltage device circuit 110 and the high voltage device circuit 120.

In addition to the DC current blocking behavior of DTI trench 130, the several interlayer dielectric layers (e.g., passivating dielectric layer 140, ILD layer 162, and ILD layer 192), and the intermetal dielectrics layers (e.g., IMD layer 172, IMD layer 174, IMD layer 176, IMD layer 271, IMD layer 273, IMD layer 276, etc.) in semiconductor die 200 have DC current blocking characteristics that prevent DC current circulation between, and help galvanically isolate, low voltage device circuit 110 from high voltage device circuit 120.

Methods for fabricating a single semiconductor die (e.g., semiconductor die 100, semiconductor die 200) including two circuits (e.g., low voltage device circuit 110 and high voltage device circuit 120) that are mutually galvanically isolated may involve bonding two semiconductor wafers (in which the two circuits are formed) together. The single semiconductor die including two galvanically isolated circuits is obtained by singulating the bonded pair of the semiconductor wafers. In an example, as discussed with reference to FIG. 1B, both of the two circuits may be formed in one of the two semiconductor wafers. In another example, as discussed with reference to FIG. 2, the two circuits may be formed individually in a respective one of the two semiconductor wafers. The two circuits may be spatially separated by a distance (e.g., distance DC, FIG. 1A) in the x direction along a top surface of the semiconductor die. The two circuits may be galvanically isolated from each other by dielectric-filled deep trench isolation trenches (e.g., DTI trench 130, FIG. 1A) disposed between the two circuits. In some example methods, the DTI trench 130 may be formed before the bonding of the two semiconductor wafers. Is some other example methods, the DTI trench 130 may be formed after the bonding of the two semiconductor wafers.

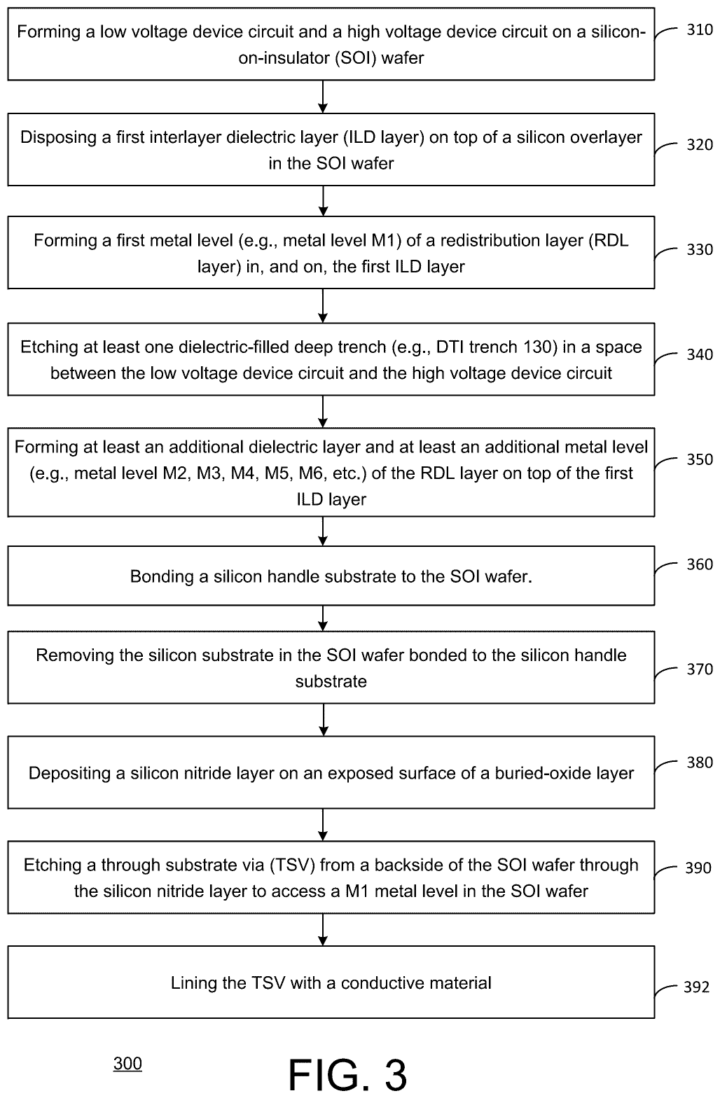

FIG. 3 illustrates an example method 300 for fabricating a single semiconductor die (e.g., semiconductor die 100) including two circuits (e.g., low voltage device circuit 110 and high voltage device circuit 120) that are galvanically isolated from each other, in accordance with the principles of the present disclosure.

Method 300 includes forming a low voltage device circuit and a high voltage device circuit on a silicon-on-insulator (SOI) wafer (310). The SOI wafer may include a silicon overlayer disposed on a buried oxide layer formed on a silicon substrate. The low voltage device circuit and the high voltage circuit may be fabricated in the silicon over layer and separated by a spatial distance DC along a surface of the SOI wafer.

Method 300 further includes disposing a first interlayer dielectric layer (ILD layer) (e.g. ILD layer 162) on top of a silicon overlayer in the SOI wafer (320), and forming a first metal level (e.g., metal level M1) of a redistribution layer (RDL layer) in, and on, the first ILD layer (330). Portions of metal level M1 may be disposed on the first ILD layer as an inductor spiral (e.g., spiral 412S) above low voltage device circuit 110. Other portions of metal level M1 may be disposed in or on the first ILD layer as an inductor spiral (e.g., spiral 422S) above the high voltage device circuit 120.

Method 300 may further include etching at least one dielectric-filled deep trench (e.g., DTI trench 130) in a space between the low voltage device circuit and the high voltage device circuit (340) The DTI trench 130 may extend through the combined thicknesses of the first ILD layer and the silicon overlayer. The DTI trench 130 may be filled with insulating material (e.g., silicon oxide, silicon nitride, etc.). The dielectric-filled DTI trench 130 may block DC current paths between the low voltage device circuit and the high voltage device circuit.

Method 300 may include forming at least an additional dielectric layer and at least an additional metal level (e.g., metal level M2, M3, M4, M5, M6, etc.) of the RDL layer on top of the first ILD layer (350). For example, metal level M6 may be formed in or on a sixth intermetal dielectric (IMD) layer. In example implementations, portions of metal level M6 may be disposed in or on the sixth IMD layer as an inductor spiral (e.g., spiral 462S) above the low voltage device circuit. Other portions of metal level M6 may be disposed on the sixth IMD layer as an inductor spiral (e.g., spiral 466S) above the high voltage device circuit.

In example implementations, metal level M1 and metal level M6 may be inductively coupled to allow passage of AC signals between the low voltage device circuit and the high voltage device circuit.

Method 300 further includes bonding a handle substrate (a silicon handle substrate) to the SOI wafer (360). The handle substrate may have an oxide layer disposed on its top surface. The bonding may include placing the handle substrate upside down on the SOI wafer so that the oxide layer on the handle substrate is aligned with, and in contact with, a topmost IMD layer (e.g., the sixth IMD layer) on the SOI wafer. An oxide-to-oxide bond may be formed along the interface of the oxide layer on the handle substrate and the topmost IMD layer on the SOI wafer.

Method 300 further includes removing the silicon substrate in the SOI wafer bonded to the handle substrate (370). The silicon substrate in the SOI wafer may be removed, for example, by grinding and or etching and polishing processes. Removing the silicon substrate may expose the buried-oxide layer of the SOI wafer.

Method 300 further depositing a silicon nitride layer on an exposed surface of the buried-oxide layer (380), etching a through substrate via (TSV) from a backside of the SOI wafer though the silicon nitride layer to access a MI metal level in the SOI wafer (390), and lining the TSV with a conductive material (392). An insulating spacer layer may be disposed on the walls of the TSV to isolate the substrate material from the conductive material in the TSV.

In some implementations of method 300, lining the TSV with a conductive material 392 may include disposing the conductive material (e.g., a metal) in the TSV to connect metal level MI to a bond pad 154B formed on the top surface of the silicon nitride layer. Further, a protective polyimide layer may be deposited on exposed portions of the top surface of the protective dielectric layer 410.

FIGS. 4A through 4I illustrate plan views or cross-sectional views of semiconductor wafers being processed through multiple steps of a semiconductor die fabrication process according to the method of FIG. 3, in accordance with the principles of the present disclosure.

FIG. 4A and FIG. 4B illustrate a top plan view and a cross sectional view of a silicon wafer 400 at the start of the process of example method 300 for making semiconductor die 100 (FIGS. 1A-1B). Silicon wafer 400 may, for example, a silicon-on-insulator wafer including a silicon overlayer 401 formed on a buried-oxide layer 402 that is formed on a silicon substrate 403. Silicon overlayer 401 may correspond to device wafer 160 in the semiconductor die 100 and buried-oxide layer 402 may correspond to interlayer dielectric layer (e.g., ILD layer 162) in the semiconductor die 100 (FIG. 1B). In example implementations, silicon overlayer 401 may have a thickness in range of about 5 μm to 20 μm (e.g., 10 μm), and buried-oxide layer 402 may have a thickness in range of about 500 nm to 1000 nm (e.g., 700 nm).

FIG. 4C and FIG. 4D illustrate a top plan view and a cross sectional view of silicon wafer 400 after the initial processing steps of method 300. In the processing steps, low voltage device circuit 110 and high voltage device circuit 120 (separated by a distance DC in the x direction) are formed in silicon overlayer 401. An interlayer dielectric layer (e.g., ILD layer 162) is formed on top of silicon overlayer 401. ILD layer 162 may be made of silicon oxide. A first metal level (e.g., metal level M1) of a RDL layer for connecting low voltage device circuit 110 and high voltage device circuit 120 is formed in, and on, ILD layer 162. Portions of metal level M1 are disposed on ILD layer 162 as an inductor spiral (e.g., spiral 412S) above low voltage device circuit 110. Other portions of metal level Ml are disposed on ILD layer 162 as an inductor spiral (e.g., spiral 422S) above high voltage device circuit 120.

Furthermore, in the processing steps, a plurality of deep trenches (e.g., DTI trench 130) are etched through a combined thickness of silicon overlayer 401 and ILD layer 162. The DTI trench 130 may be etched in a space between low voltage device circuit 110 and high voltage device circuit 120. The deep trenches are filled with insulating material 132 (e.g., silicon oxide, silicon nitride, etc.) and block circulation of DC current between the two circuits.

Further, in additional processing step as of method 300, one or more additional metal levels (e.g., metal levels M2, M3, M4, M5, M6, et.) of a RDL (e.g., RDL 170) are formed on top of ILD layer 162. These metal levels may be embedded in or on respective IMD layers (e.g., IMD layer 174, IMD layer 176, etc.)

FIG. 4E and FIG. 4F illustrate a top plan view and a cross sectional view of silicon wafer 400 after additional metal levels of a RDL layer (e.g., RDL 170, FIG. 1B) are formed on top of ILD layer 162.

As shown, for example, in FIG. 4E and FIG. 4F, RDL 170 may include a metal level (e.g., metal level M6) formed in and on an IMD layer 176 disposed above IMD layer 172. Portions of metal level M6 are disposed on or in ILD layer 162 as an inductor spiral (e.g., spiral 462S) above low voltage device circuit 110. Other portions of metal level M6 are disposed in or on IMD layer 176 as an inductor spiral (e.g., spiral 466S) above high voltage device circuit 120. The M6 inductor spirals (e.g., spiral 462S and 466S) may be directly above the M1 inductor spirals (e.g., spirals 412S and 422S) formed in or on IMD layer 172 below. The M6 inductor spirals (e.g., spiral 462S and spiral 466S) may be inductively coupled to the M1 inductor spirals (e.g., spirals 412S and 422S) as represented, for example, by inductors 112 and 122 in FIG. 4F.

Next, as shown in FIG. 4G, a handle substrate 190 is bonded to silicon wafer 400. Handle substrate 190 may have an ILD layer 192 (e.g., a silicon oxide layer) disposed on a top surface S3 of the handle substrate. Handle substrate 190 is placed face down on silicon wafer 400 so that ILD layer 192 is aligned with and in contact with IMD layer 176 on top of wafer 400. Handle substrate 190 is bonded to silicon wafer 400 by an oxide-oxide bond formed along interface B between IMD layer 176 and ILD layer 192 disposed on handle substrate 190.

Next, as shown in FIG. 4H, silicon substrate 403 is removed from silicon wafer 400 in the bonded pair of silicon wafer 400 and handle substrate 190. Silicon substrate 403 may be removed from the bonded pair, for example, by back grinding and wet etching processes.

Next, the bonded pair of silicon wafer 400 and handle substrate 190 is placed upside down so that buried-oxide layer 402 is at a top of the structure and handle substrate 190 is at a bottom of the structure. Further, as shown in FIG. 4I, a protective dielectric layer 410 (e.g., silicon nitride) may be deposited on buried-oxide layer 402 at the top of the structure. A through-substrate via (e.g., TSV 152) may be etched through the protective dielectric layer 410, silicon overlayer 401 and ILD layer 162 to access the metallization level M1.

A conductive material liner (e.g., metal liner 154) may be disposed in TSV 152 to connect metal level M1 to a bond pad 154B formed on the top surface of the protective dielectric layer 410 (e.g., silicon nitride layer). Further, a protective polyimide layer (e.g., layer 420) may be deposited on exposed portions of the top surface of the protective dielectric layer 410.

The next process steps may involve singulation (not shown) to extract individual semiconductor die (e.g., semiconductor die 100) that include both the low voltage device circuit and the high voltage device circuit that are galvanically isolated from each other.

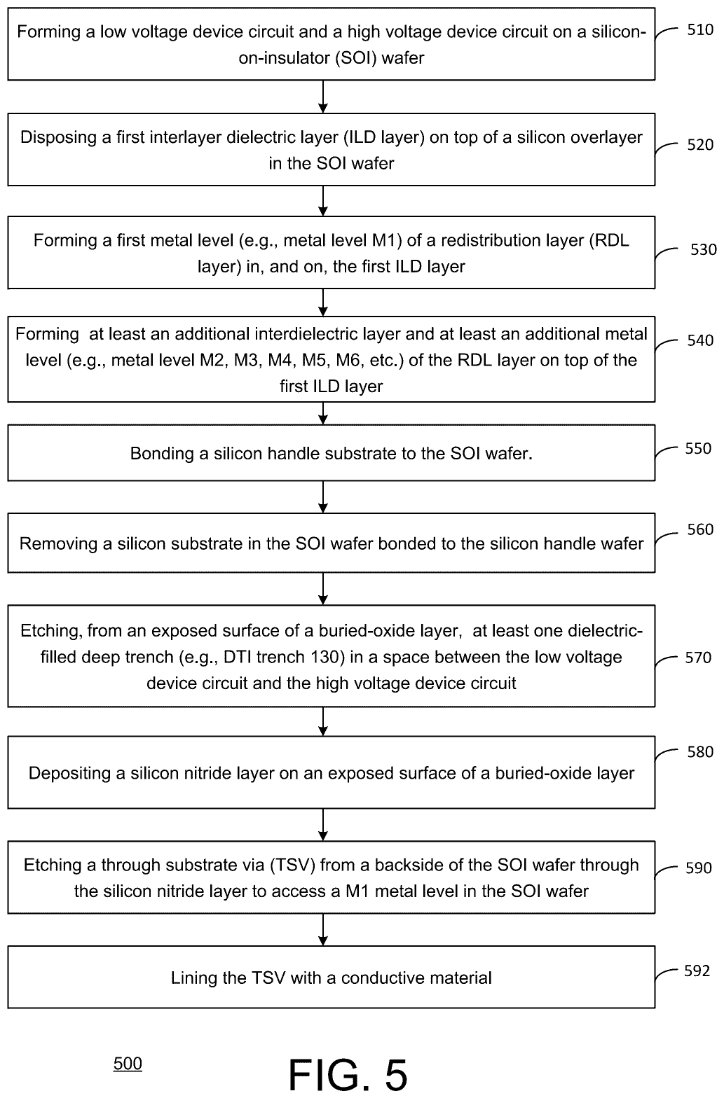

FIG. 5 illustrates another example method 500 for making a single semiconductor die (e.g., semiconductor die 100) including two circuits (e.g., low voltage device circuit 110 and high voltage device circuit 120) that are mutually galvanically isolated, in accordance with the principles of the present disclosure.

Method 500 includes forming a low voltage device circuit and a high voltage device circuit on a silicon-on-insulator (SOI) wafer (510). The SOI wafer may include a silicon overlayer disposed on a buried oxide layer formed on a silicon substrate. The low voltage device circuit and the high voltage circuit may be fabricated in the silicon overlayer and separated by a spatial distance DC along a surface of the SOI wafer.

Method 500 further includes disposing a first interlayer dielectric layer (ILD layer) (e.g. ILD layer 162) on top of a silicon overlayer in the SOI wafer (520), and forming a first metal level (e.g., metal level M1) of a redistribution layer (RDL layer) in, and on, the first ILD layer (530). Portions of metal level M1 may be disposed on the first ILD layer as an inductor spiral (e.g., spiral 412S) above low voltage device circuit 110. Other portions of metal level M1 may be disposed on the first ILD layer as an inductor spiral (e.g., spiral 422S) above the high voltage device circuit 120.

Method 500 may include forming at least an additional inter dielectric layer and at least an additional metal level (e.g., metal level M2, M3, M4, M5, M6, etc.) of the RDL layer on top of the first ILD layer (540). For example, metal level M6 may be formed in or on a sixth inter metal dielectric (IMD) layer. In example implementations, portions of metal level M6 may be disposed in or on the sixth IMD layer as an inductor spiral (e.g., spiral 462S) above low voltage device circuit. Other portions of metal level M6 may be disposed on the sixth ILD layer as an inductor spiral (e.g., spiral 466S) above the high voltage device circuit.

In example implementation, metal level M1 and metal level M6 may be inductively coupled to allow passage of AC signals between the low voltage device circuit and the high voltage device circuit.

Method 500 further includes bonding a handle substrate to the SOI wafer (550). The handle substrate may have an oxide layer disposed on its top surface. The bonding may include placing the handle substrate upside down on the SOI wafer so that the oxide layer on the handle substrate is aligned with and in contact a topmost IMD layer (e.g., the sixth IMD layer) on the SOI wafer. An oxide-to-oxide bond may be formed along the interface of the oxide layer on the handle substrate and the topmost IMD layer on the SOI wafer.

Method 500 further includes removing the silicon substrate in the SOI wafer bonded to the handle substrate (560). The silicon substrate in the SOI wafer may be removed, for example, by grinding and or etching and polishing processes. Removing the silicon substrate may expose the buried-oxide layer of the SOI wafer.

Method 500 may further include etching, from an exposed surface of the buried-oxide layer, at least one dielectric-filled deep trench (e.g., DTI trench 130) in a space between the low voltage device circuit and the high voltage device circuit (570) The DTI trench 130 may extend through the combined thicknesses of the buried oxide layer and the silicon overlayer of the SOI wafer. The DTI trench 130 may be filled with insulating material (e.g., silicon oxide, silicon nitride, etc.). The dielectric-filled DTI trench 130 may block DC current paths between the low voltage device circuit and the high voltage device circuit.

Method 500 further includes depositing a silicon nitride layer on an exposed surface of the buried-oxide layer (580), etching a through substrate via (TSV) from a backside of the SOI wafer though the silicon nitride layer to access a MI metal level in the SOI wafer (590), and lining the TSV with a conductive material (592).

In some implementations of method 500, lining the TSV with a conductive material 392 may include disposing the conductive material (e.g., a metal) in the TSV to connect metal level M1 to a bond pad 154B formed on the top surface of the silicon nitride layer. Further, a protective polyimide layer may be deposited on exposed portions of the top surface of the protective dielectric layer 410.

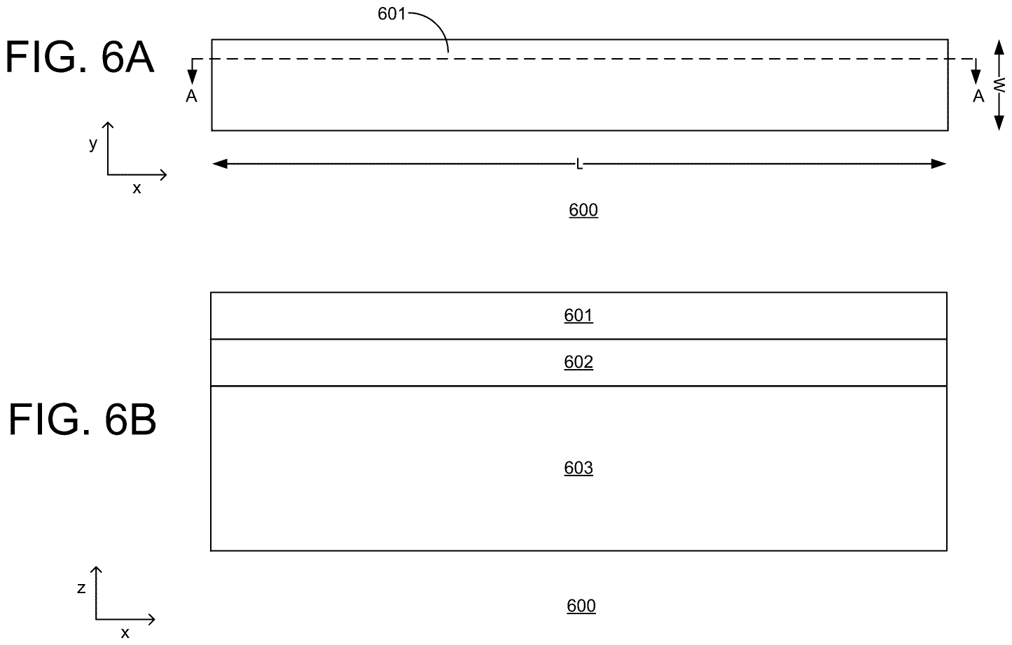

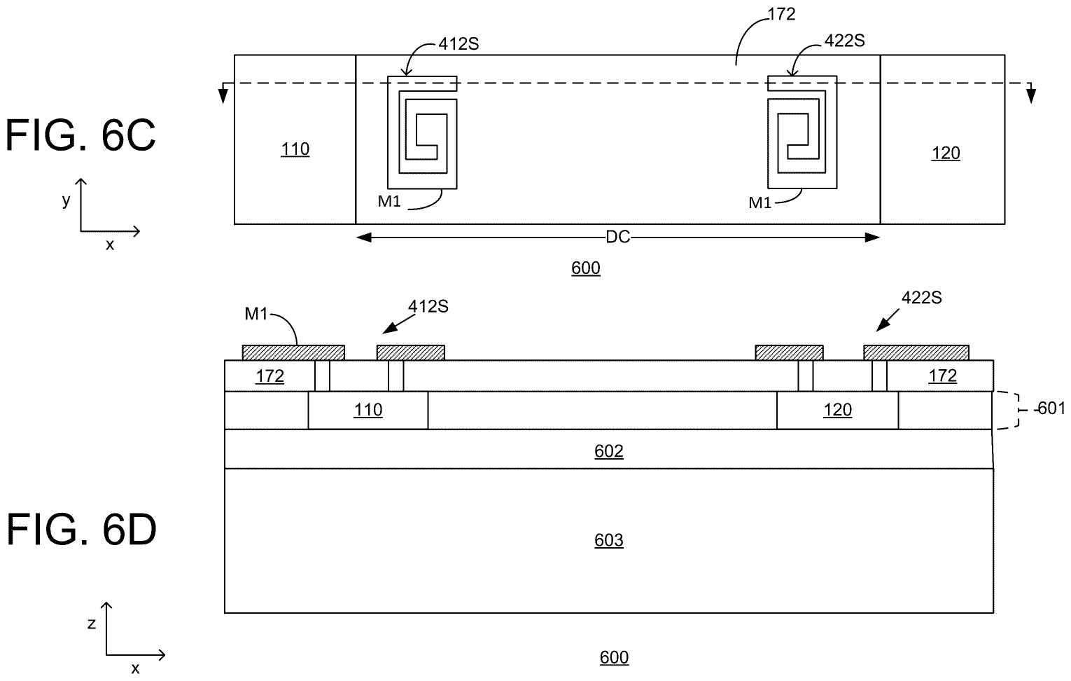

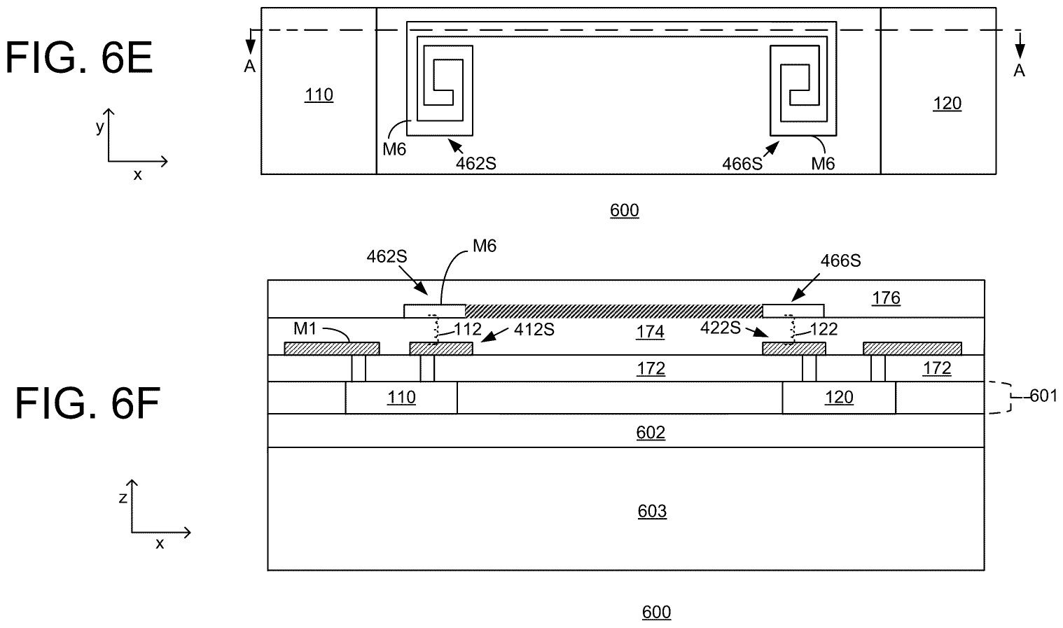

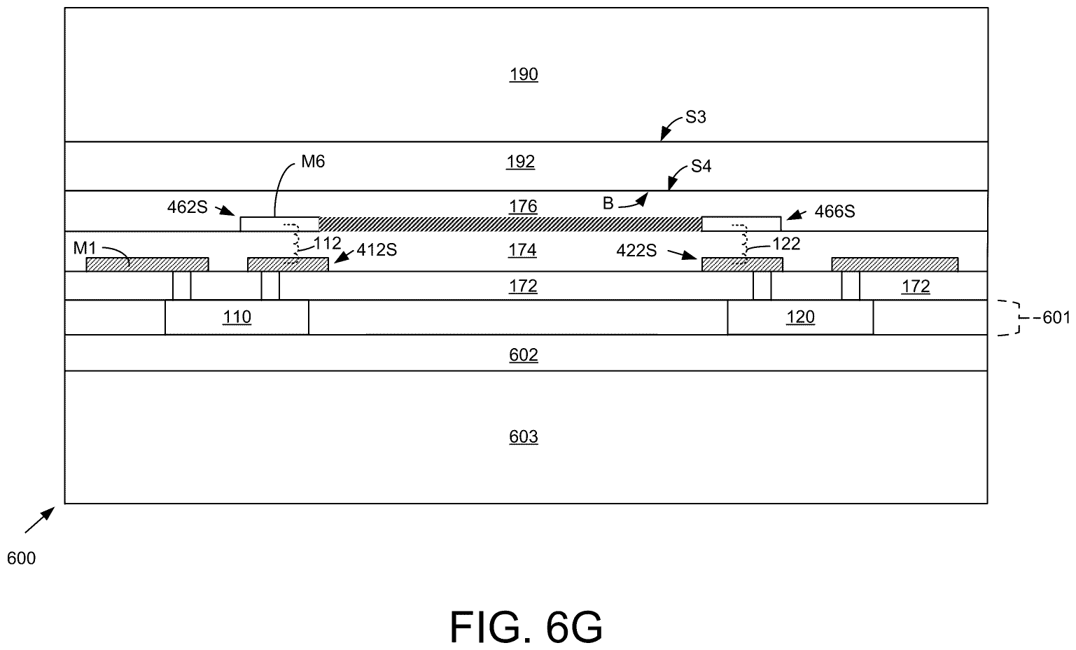

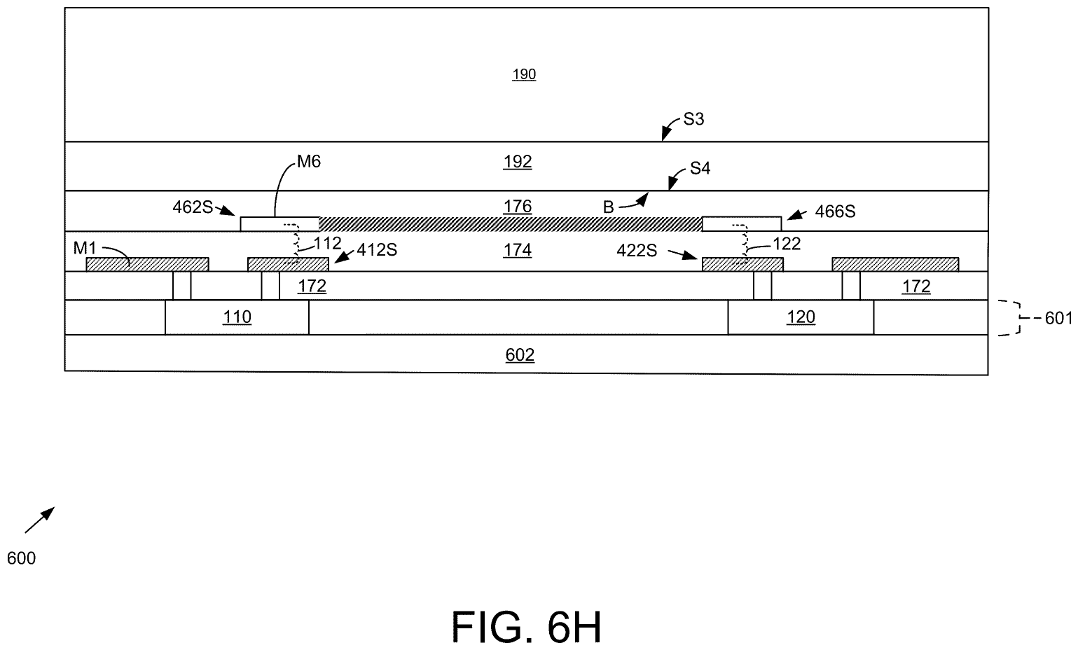

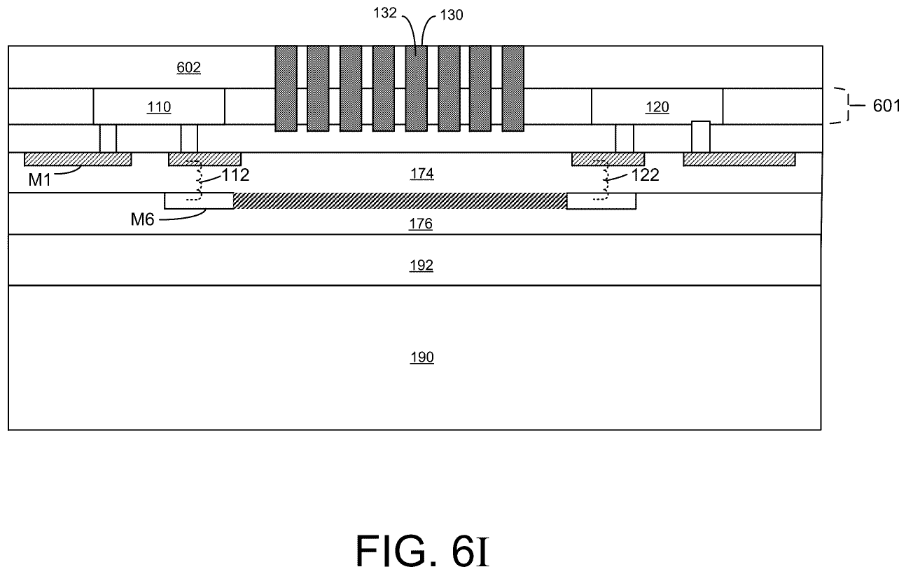

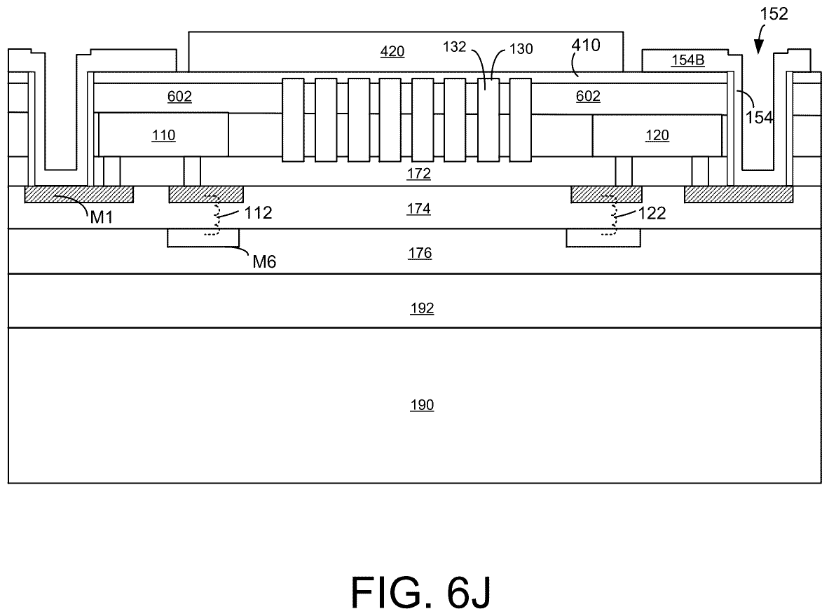

FIGS. 6A through 6J illustrate plan views or cross-sectional views of semiconductor wafers being processed through multiple steps of a semiconductor die fabrication process according to the method of FIG. 5, in accordance with the principles of the present disclosure.

FIG. 6A and FIG. 6B illustrate a top plan view and a cross sectional view of a silicon wafer 600 at the start of the process of example method 300 for making semiconductor die 100 (FIGS. 1A-1B). Silicon wafer 600 (like silicon wafer 400, FIG. 4A and FIG. 4B) may, for example, a silicon-on-insulator wafer including a silicon overlayer 601 formed on a buried-oxide layer 602 that is formed on a silicon substrate 603. Silicon overlayer 601 may correspond to device wafer 160 in the semiconductor die 100 (FIG. 1B) and buried-oxide layer 602 may correspond to interlayer dielectric layer (e.g., ILD layer 162) in the semiconductor die 100 (FIG. 1B). In example implementations, silicon overlayer 601 may have a thickness in range of about 5 μm to 20 μm (e.g., 10 μm), and buried-oxide layer 602 may have a thickness in range of about 500 nm to 1000 nm (e.g., 700 nm).

FIG. 6C and FIG. 6D illustrate a top plan view and a cross sectional view of silicon wafer 600 after the front end of the line (FEOL) processing steps of method 500. In the processing steps, low voltage device circuit 110 and high voltage device circuit 120 (separated by a distance DC in the x direction) are formed in silicon overlayer 401. An interlayer dielectric layer (e.g., ILD layer 162) is formed on top of silicon overlayer 401. ILD layer 162 may be made of silicon oxide. A first metal level (e.g., metal level M1) of a RDL layer for connecting low voltage device circuit 110 and high voltage device circuit 120 is formed in, and on, ILD layer 162. Portions of metal level M1 are disposed on ILD layer 162 as an inductor spiral (e.g., spiral 412S) above low voltage device circuit 110. Other portions of metal level M1 are disposed on ILD layer 162 as an inductor spiral (e.g., spiral 422S) above high voltage device circuit 120.

Further, in additional processing step of method 500, one or more additional metal levels (e.g., metal levels M2, M3, M4, M5, M6, et.) of an RDL layer (e.g., RDL 170, FIG. 1B) are formed on top of ILD layer 162. These metal levels may be embedded in or disposed on respective IMD layers (e.g. IMD layer 174, IMD layer 176, etc.)

FIG. 6E and FIG. 6F illustrate a top plan view and a cross sectional view of silicon wafer 400 after additional metal levels of an RDL layer (e.g., RDL 170) are formed on top of ILD layer 162.

As shown, for example, in FIG. 6E and FIG. 6F, RDL 170 may include a higher or outermost metal level (e.g., metal level M6) formed in or disposed in on an outermost IMD layer (e.g., IMD layer 176). For example, the outermost metal level may be metal level M6 disposed in IMD layer 176 above IMD layer 172. Portions of metal level M6 are disposed in IMD layer 176 as an inductor spiral (e.g., spiral 462S) above low voltage device circuit 110. Other portions of metal level M6 are disposed in or on IMD layer 176 as an inductor spiral (e.g., spiral 466S) above high voltage device circuit 120. The M6 inductor spirals (e.g., spiral 462S and 466S) may be directly above the M1 inductor spirals (e.g., spirals 412S and 422S) formed in or on IMD layer 172 below. The M6 inductor spirals (e.g., spiral 462S and spiral 466S) may be inductively coupled to the M1 inductor spirals (e.g., spirals 412S and 422S) as represented, for example, by inductors 112 and 122 in FIG. 6F.

Next, as shown in FIG. 6G, a handle substrate 190 is bonded to silicon wafer 600. Handle substrate 190 may have an ILD layer 192 disposed on a top surface S3 of the handle substrate. Handle substrate 190 is placed face down on silicon wafer 600 so that ILD layer 192 is aligned with and in contact with IMD layer 176 on top of wafer 600. Handle substrate 190 is bonded to silicon wafer 600 by an oxide-oxide bond formed along interface B between IMD layer 176 and ILD layer 192 disposed on handle substrate 190.

Next, as shown in FIG. 6H, silicon substrate 603 is removed from silicon wafer 600 in the bonded pair of silicon wafer 600 and handle substrate 190. Silicon substrate 603 may be removed from the bonded pair, for example, by back grinding and wet etching processes.

Next, the bonded pair of silicon wafer 600 and handle substrate 190 is placed upside down so that buried-oxide layer 602 is at a top of the structure and handle substrate 190 is at a bottom of the structure. Furthermore, a plurality of deep trenches (e.g., DTI trench 130) are etched from a top surface of buried-oxide layer 602 through a combined thickness of buried-oxide layer 602 and silicon overlayer 601. The DTI trench 130 may be etched in a space between low voltage device circuit 110 and high voltage device circuit 120. The deep trenches are filled with insulating material 132 (e.g., silicon oxide, silicon nitride, etc.) which can block circulation of DC current between the two circuits.

Further, as shown in FIG. 6I, a protective dielectric layer 410 (e.g., silicon nitride) may be deposited over a top of buried-oxide layer 402 and the tops of the dielectric-filled deep trenches (e.g., DTI trench 130) at the top of the structure. A through-substrate via (e.g., TSV 152) may be etched through the protective dielectric layer 410, silicon overlayer 401 and ILD layer 162 to access the metallization level M1.

A conductive material liner (e.g., metal liner 154) may be disposed in TSV 152 to connect metal level M1 to a bond pad 154B formed on the top surface of the protective dielectric layer 410 (e.g., silicon nitride layer). Further, a protective polyimide layer (e.g., layer 420) may be deposited on exposed portions of the top surface of the protective dielectric layer 410.

The next process steps may involve singulation (not shown) to extract individual semiconductor die (e.g., semiconductor die 100) that include both the low voltage device circuit and the high voltage device circuit that are galvanically isolated from each other.

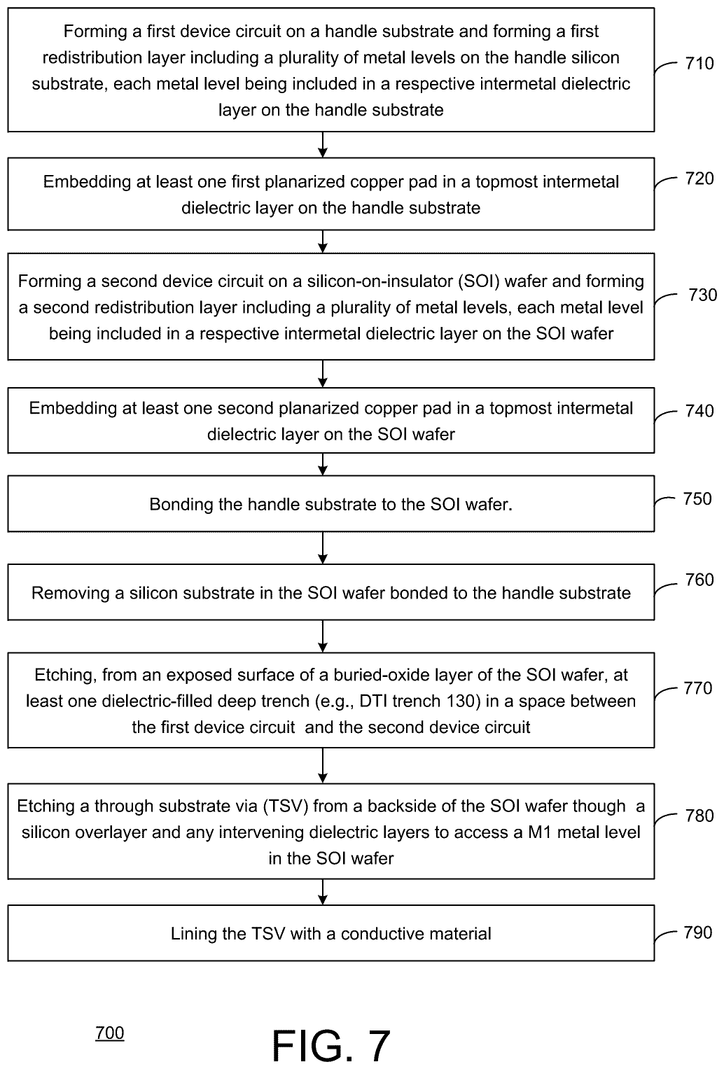

FIG. 7 illustrates another example method 700 for making a single semiconductor die (e.g., semiconductor die 200) including two circuits (e.g., low voltage device circuit 110 and high voltage device circuit 120) that are mutually galvanically isolated, in accordance with the principles of the present disclosure.

Method 700 includes forming a first device circuit on a handle substrate, and forming a first redistribution layer including a plurality of metal levels on the handle substrate, each metal level being included in a respective intermetal dielectric layer on the handle substrate (710).

Method 700 further includes embedding at least one first planarized copper pad in a topmost intermetal dielectric layer on the handle substrate (720). The topmost intermetal dielectric layer may be a silicon oxide layer and the at least first planarized copper pad may be connected to a topmost metal level (e.g., metal level M6) included in the topmost intermetal dielectric layer on the handle substrate.

Method 700 includes forming a second device circuit on a silicon-on-insulator (SOI) wafer, and forming a second redistribution layer including a plurality of metal levels, each metal level being included in a respective intermetal dielectric layer on the SOI wafer (730). The SOI wafer may include a silicon overlayer disposed on a buried oxide layer, which is formed on a silicon substrate.

Method 700 further includes embedding at least one second planarized copper pad in a topmost intermetal dielectric layer on the SOI wafer (740). The topmost intermetal dielectric layer may be a silicon oxide layer and the at least one second planarized copper pad may be connected to a topmost metal level (e.g., metal level M6) included in the topmost intermetal dielectric layer on the SOI wafer.

Method 700 further includes bonding the handle substrate to the SOI wafer (750). The bonding may be a hybrid bonding involving oxide-to-oxide bonding and metal-to-metal bonding. The bonding may include placing the SOI wafer face down on the handle substrate with the surfaces of the topmost intermetal dielectric layers on the SOI wafer and the handle substrate in contact with each other, and the at least one first planarized copper pad aligned with and in contact with the at least one second planarized copper pad.

The handle substrate and the SOI wafer may be oriented so that first device circuit in the handle substrate and the second device circuit in the SOI wafer are separated from each other by a distance DC in a direction parallel to a top surface the handle substrate or the SOI wafer. The metal-to-metal bonding of the at least one first planarized copper pad and the at least one second planarized copper pad may connect the metal level M6 of the SOI wafer with M6 level of the handle substrate.

Method 700 further includes removing a silicon substrate in the SOI wafer bonded to the handle substrate (760). The silicon substrate in the SOI wafer may be removed, for example, by grinding and or etching and polishing processes. Removing the silicon substrate may expose a buried-oxide layer of the SOI wafer.

Method 700 may further include etching, from an exposed surface of the buried-oxide layer, at least one dielectric-filled deep trench (e.g., DTI trench 130) in a space between the first device circuit and the second device circuit (770). The DTI trench 130 may extend through the combined thicknesses of the buried-oxide layer and the silicon overlayer of the SOI wafer. The DTI trench 130 may be filled with insulating material (e.g., silicon oxide, silicon nitride, etc.). The dielectric-filled DTI trench 130 may block DC current paths between the first device circuit and the second device circuit.

Method 700 may further include etching a through substrate via (TSV) from a backside of the SOI wafer through a silicon overlayer and any intervening dielectric layers to access a M1 metal level in the SOI wafer (780), and lining the TSV with a conductive material (790).

In some implementations of method 700, lining the TSV with a conductive material 790 may include disposing the conductive material (e.g., a metal) in the TSV to connect metal level MI to a bond pad 154B formed on a top surface of the SOI wafer. Further, a protective polyimide layer may be deposited on exposed portions of the top surface of the SOI wafer.

A semiconductor die (e.g., semiconductor die 200) with two galvanically device circuits may be formed by singulation of the bonded pair of SOI wafer and handle substrate.

It will be appreciated that methods described above illustrate an example sequence of manufacturing operations, but that the various operations may occur in a different order than that shown and/or may have more or fewer operations than that shown. For example, depending on available testing and packaging options or preferences, singulation may occur prior to some or all testing operations.

Galvanically isolating two circuits on a single semiconductor die instead of using two individual semiconductor dies for two circuits can beneficially result in lower die cost (one die vs two die), lower package cost, smaller form factor, lower testing costs and higher reliability.

The technique of using dielectric-filled deep isolation trenches to galvanic isolate functional sections of electrical systems on a single semiconductor die has been described above to achieve galvanic isolation between two functional sections (e.g., a low voltage device circuit and a high voltage device circuit) of an electrical system on a single die. The technique can also be used to achieve galvanic isolation between multiple (greater than two) functional sections of an electrical system on a single die.

For example, the technique of using dielectric-filled deep isolation trenches can be used in three-phase power supply circuits (e.g., in a three-phase traction inverter) to individually galvanically isolate each the three functional sections of the power supply circuit corresponding to a respective one of the three phases.

Current three-phase traction inverters are fabricated using at least three die packages with each package including two dies for two switches in each of the three phases of the three-phase traction inverter. Thus, in some implementations, 2×3=six dies may be needed to construct a three-phase traction inverter. Using the galvanic isolation techniques described in the foregoing, a complete three-phase traction inverter with three galvanically isolated phase sections can instead be fabricated on a single die.

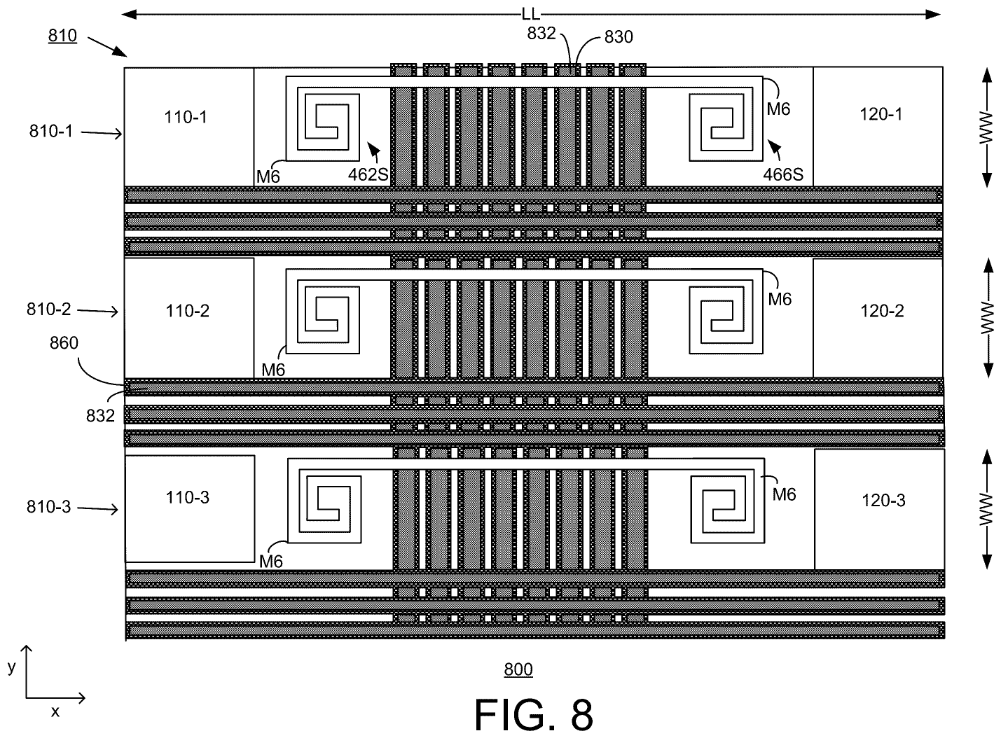

FIG. 8 is a plan view of an example three-phase inverter circuit 810 fabricated on a single die 800. Three-phase inverter circuit 810 may include three sections 810-1, 810-2, and 810-3 corresponding to phase 1, phase 2, and phase 3 of the signals transmitted through the three-phase inverter circuit 810. As shown in FIG. 8, the three sections 810-1, 810-2, and 810-3 may extend parallel to each other in the x direction in die 800.

Each of the three sections 810-1, 810-2, and 810-3 in die 800 may, for example, have a length LL in the x direction and a width WW in the y direction. Each of the three sections 810-1, 810-2, and 810-3 may include a low voltage device circuit or switch (e.g., switch 110-1, 110-2, and 110-3, respectively) at one end of the die, and include a high voltage device circuit or switch (e.g., switch 120-1, 120-2, and 120-3, respectively) at an opposite end of the die. The low voltage device circuit or switch and the high voltage device circuit or switch may, for example, include MOSFET devices. These circuits and devices may be fabricated in a silicon overlayer of an SOI wafer (not shown) in a manner similar to that previously described for semiconductor die 100 (with reference to FIGS. 4A and 4B).

In example implementations, in each of the three sections 810-1, 810-2, and 810-3, the low voltage device circuit or switch (e.g., switch 110-1, 110-2, or 110-3, respectively) may be galvanically isolated in the x direction from the corresponding high voltage device circuit or switch (e.g., switch 120-1, 120-2, or 120-3, respectively) by a plurality of dielectric-filled deep isolation trenches (e.g., DTI trench 830) extending in the y direction between the low voltage device circuit or switches (e.g., switch 110-1, 110-2, and 110-3) at one end of the die and the high voltage device circuit or switches (e.g., switch 120-1, 120-2, and 120-3) at the opposite end of the die. The DTI trench 830 may be filled with insulating dielectric material 832 (e.g., silicon oxide, or silicon nitride, etc.).

The DTI trench 830 may prevent circulation of DC current between the low voltage device circuit or switch (e.g., switch 110-1, 110-2, or 110-3) at one end of the die and the corresponding high voltage device circuit or switch (e.g., switch 120-1, 120-2, or 120-3, respectively) at the opposite end of the die in each of the three sections 810-1, 810-2, and 810-3. In each of the three sections 810-1, 810-2, and 810-3, passage of AC signals between the low voltage device circuit or switch and the high voltage device circuit or switch can take place through inductive or capacitive coupling of the metal levels in the redistribution layers of the devices in the sections, as discussed above with reference to semiconductor die or semiconductor die 200.

FIG. 8 shows, for example, portions of metal level M6 in each section forming inductor spirals (e.g., spiral 462S, spiral 466S) on or about a top surface of die 800. The M6 inductor spirals (e.g., spiral 462S and 466S) may be directly above the M1 inductor spirals (e.g., spirals 412S and 422S, FIG. 4B) formed below (not shown in FIG. 8). The M6 inductor spirals (e.g., spiral 462S and spiral 466S) may be inductively coupled to the M1 inductor spirals (e.g., spirals 412S and 422S) as represented, for example, by inductors 112 and 122 in FIG. 4F. These inductors may allow passage of AC signals in each of the three sections 810-1, 810-2, and 810-3 between the low voltage device circuit or switch (e.g., switch 110-1, 110-2, and 110-3, respectively) and the corresponding high voltage device circuit or switch (e.g., switch 120-1, 120-2, and 120-3, respectively).

Furthermore, each of the three sections 810-1, 810-2, and 810-3 may be galvanically isolated from each other in the y direction by at least a dielectric-filled deep isolation trench (e.g., DTI trench 860) extending between the adjacent sections in the x direction for at least the length LL of the sections. In other words, for each pair of adjacent sections, at least a dielectric-filled deep isolation trench extends between the adjacent sections in the x direction to galvanically isolate the pair of adjacent sections.

The DTI trench 860, like DTI trench 830, may be filled with dielectric material 832 (e.g., silicon oxide, or silicon nitride, etc.) to prevent circulation of DC current between the three sections 810-1, 810-2, and 810-3.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the embodiments.

What is claimed is:

1. A semiconductor die, comprising:
a silicon layer;
a first device circuit formed in a first region at a first end of the silicon layer; and
a second device circuit formed in a second region at a second end of a silicon layer at a distance from the first region, the first end being opposite the second end, the first device circuit being galvanically isolated from the second device circuit.

2. The semiconductor die of claim 1, further comprising:
an interlayer dielectric (ILD) layer disposed on a bottom surface of the silicon layer; and
at least one dielectric-filled trench disposed in a space between the first device circuit and the second device circuit, the at least one dielectric-filled trench extending through a combined thickness of the silicon layer and the ILD layer disposed on the bottom surface of the silicon layer.

3. The semiconductor die of claim 2, wherein the at least one dielectric-filled trench is filled with insulating material including at least one of silicon oxide and silicon nitride.

4. The semiconductor die of claim 2, further comprising:
a redistribution layer formed on the ILD layer, the redistribution layer including a plurality of metal levels, each of the plurality of metal levels being embedded in, or disposed on, a respective intermetallic dielectric (IMD) layer, the plurality of metal levels including:
a first metal level embedded in a first IMD layer, the first metal level having a first portion connected to the first device circuit and a second portion connected to the second device circuit; and
a higher metal level embedded in a higher IMD layer or an outermost IMD layer.

5. The semiconductor die of claim 4, wherein a first metal level M1 is inductively or capacitively coupled to the higher metal level embedded in the higher IMD layer or the outermost IMD layer to provide an AC signal path between the first device circuit and the second device circuit.

6. The semiconductor die of claim 4, wherein the first portion of the first metal level is disposed on the first ILD layer as an inductor spiral above the first device circuit and the second portion of the first metal level is disposed on the first ILD layer as an inductor spiral above the second device circuit.

7. The semiconductor die of claim 6, wherein the higher metal level is disposed as a first inductor spiral directly above the inductor spiral formed by the first portion of the first metal level and as a second inductor spiral directly above the second portion of first metal level.

8. The semiconductor die of claim 4, further comprising:
a handle substrate disposed below and bonded to the outermost IMD layer of the redistribution layer by an oxide-to-oxide bond between the outermost IMD layer and a silicon oxide layer disposed on the handle substrate.

9. A semiconductor die, comprising:
a silicon layer;
a first device circuit formed in the silicon layer in a first region at a first end of the semiconductor die;
a handle substrate;
a second device circuit formed in the handle substrate in a second region at a second end of the semiconductor die; and
a plurality of dielectric layers disposed between the handle substrate and the silicon layer, and
the first device circuit in the silicon layer being galvanically isolated from the second device circuit formed in the handle substrate by the plurality of dielectric layers coupling the handle substrate and the silicon layer.

10. The semiconductor die of claim 9, wherein the plurality of dielectric layers includes:
a first interlayer dielectric (ILD) layer disposed on a bottom surface of the silicon layer;
a first redistribution layer formed on the first ILD layer, the first redistribution layer including a plurality of metal levels, the plurality of metal levels being embedded in, or disposed on, respective intermetallic dielectric (IMD) layers;
a second interlayer dielectric (ILD) layer disposed on a top surface of the handle substrate; and
a second redistribution layer formed on the second ILD layer, the second redistribution layer including a plurality of metal levels, the plurality of metal levels being embedded in, or disposed on, a respective intermetallic dielectric (IMD) layers, and
the handle substrate being disposed below and bonded to an outermost IMD layer of the first redistribution layer by an oxide-to-oxide and a metal-to-metal bond between the outermost IMD layer of the first redistribution layer and an outermost IMD layer of the second redistribution layer.

11. The semiconductor die of claim 10, further comprising:
at least one dielectric-filled trench disposed in a space between the first device circuit and the second device circuit, the at least one dielectric-filled trench extending through a combined thickness of the silicon layer and the first ILD layer disposed on the bottom surface of the silicon layer.

12. The semiconductor die of claim 10, wherein at least a first planarized copper pad is embedded in the outermost IMD layer of the first redistribution layer and at least a second planarized copper pad is embedded in the outermost IMD layer of the second redistribution layer, and wherein a metal-to-metal bond connects an outermost metal level of the first redistribution layer with an outermost metal level of the second redistribution layer.

13. The semiconductor die of claim 12, wherein a first metal level in the first redistribution layer is inductively or capacitively coupled to a higher metal level embedded in the first redistribution layer, and wherein a first metal level in the second redistribution layer is inductively or capacitively coupled to a higher metal level in the second redistribution layer to provide an AC signal path between the first device circuit and the second device circuit.

14. A semiconductor die, comprising:
three sections of a three-phase inverter circuit including a first phase section, a second phase section, and a third phase section, the three sections extending parallel to each other in a first direction in the semiconductor die and having a width in a second direction, each of the three sections including a low voltage switch at one end of the semiconductor die and a high voltage switch at an opposite end of the semiconductor die;
in each phase section, at least one dielectric-filled deep isolation trench extending in the second direction between the low voltage switch and the high voltage switch; and
for each pair of adjacent phase sections, at least one dielectric-filled deep isolation trench extending in the first direction between each pair of the adjacent phase sections.

15. The semiconductor die of claim 14, wherein the at least one dielectric-filled deep isolation trench extending in the second direction and the at least one dielectric-filled deep isolation trench extending in the first direction are filled with insulating material.

16. The semiconductor die of claim 14, wherein in each of the three sections, the low voltage switch and the high voltage switch include a MOSFET device.

17. A method, comprising:
forming a low voltage device circuit and a high voltage device circuit on a silicon-on-insulator (SOI) wafer;
disposing a plurality of dielectric layers on top of a silicon overlayer in the SOI wafer; and
etching at least one dielectric-filled deep trench in a space between the low voltage device circuit and the high voltage device circuit.

18. The method of claim 17, wherein the low voltage device circuit and the high voltage device circuit are fabricated in the silicon overlayer and separated by a spatial distance along a surface of the SOI wafer.

19. The method of claim 18, wherein disposing the plurality of dielectric layers on top of the silicon overlayer in the SOI wafer on top of a silicon overlayer includes:
disposing a first interlayer dielectric layer (ILD layer) on top of the silicon overlayer in the SOI wafer; and
forming a first metal level of a multi-metal level redistribution layer (RDL layer) in, and on, the first ILD layer; and
forming at least an additional IDL layer and at least an additional metal level of the multi-metal level of RDL layer on top of the first ILD layer.

20. The method of claim 19, wherein forming the first metal level of the multi-metal level RDL layer includes disposing portions of the first metal level as an inductor spiral above the low voltage device circuit and other portions of the first metal level as an inductor spiral above the high voltage device circuit, and
wherein forming an additional metal level of the RDL layer includes disposing portions of the additional metal level as an inductor spiral above the low voltage device circuit and other portions of the additional metal level as an inductor spiral above the high voltage device circuit.

21. The method of claim 20 further comprising:
bonding a handle substrate to the SOI wafer;
removing a silicon substrate in the SOI wafer bonded to the handle substrate;
depositing a silicon nitride layer on an exposed surface of a buried-oxide layer of the SOI wafer;
etching a through-substrate via (TSV) from a backside of the SOI wafer through the silicon nitride layer to access the first metal level; and
lining the TSV with a conductive material.

22. The method of claim 21, wherein the handle substrate has an oxide layer disposed on its top surface, and wherein bonding the handle substrate to the SOI wafer includes placing the handle substrate upside down on the SOI wafer so that the oxide layer on the handle substrate is aligned with, and in contact with, a topmost dielectric layer on the SOI wafer.

23. The method of claim 21, wherein removing the silicon substrate in the SOI wafer bonded to the handle substrate exposes the buried-oxide layer of the SOI wafer.

24. The method of claim 21, wherein lining the TSV with a conductive material includes disposing the conductive material in the TSV to connect the first metal level to a bond pad formed on a top surface of the silicon nitride layer.

25. A method, comprising:
forming a low voltage device circuit and a high voltage device circuit on a silicon-on-insulator (SOI) wafer;
disposing a plurality of dielectric layers on top of a silicon overlayer in the SOI wafer;
coupling a handle substrate to the SOI wafer;
removing a silicon substrate in the SOI wafer coupled to the handle substrate;
etching, from an exposed surface of a buried oxide layer, at least one dielectric-filled deep trench in a space between the low voltage device circuit and the high voltage device circuit;
depositing a silicon nitride layer on an exposed surface of a buried-oxide layer of the SOI wafer;
etching a through-substrate via (TSV) from a backside of the SOI wafer through the silicon nitride layer to access a metal level in the SOI wafer; and
lining the TSV with a conductive material.

26. The method of claim 25, wherein disposing a plurality of dielectric layers includes:
disposing a first interlayer dielectric layer (ILD layer) on top of the silicon overlayer in the SOI wafer;
forming a first metal level of a multi-metal level redistribution layer (RDL layer) in, and on, the first ILD layer; and
forming at least an additional interlayer dielectric layer and at least an additional metal level of the RDL layer on top of the first ILD layer.

27. The method of claim 26, wherein forming the first metal level of the multi-metal level RDL layer includes disposing portions of the first metal level as an inductor spiral above the low voltage device circuit and other portions of first metal level as an inductor spiral above the high voltage device circuit, and wherein forming an additional metal level of the multi-metal level RDL layer includes disposing portions of the additional metal level as an inductor spiral above the low voltage device circuit and other portions of the additional metal level as an inductor spiral above the high voltage device circuit.

28. The method of claim 26 wherein the handle substrate has an oxide layer disposed on its top surface, and wherein coupling the handle substrate to the SOI wafer includes placing the handle substrate upside down on the SOI wafer so that the oxide layer on the handle substrate is aligned with, and in contact with, a topmost IMD layer on the SOI wafer.

29. The method of claim 26, wherein lining the TSV with a conductive material includes disposing the conductive material in the TSV to connect the first metal level to a bond pad formed on the top surface of the silicon nitride layer.

30. A method, comprising:
forming a first device circuit on a handle substrate and forming a first redistribution layer including a plurality of metal levels, each metal level being included in a respective intermetal dielectric layer on the handle substrate;
embedding at least one first planarized metal pad in a topmost intermetal dielectric layer on the handle substrate;
forming a second device circuit on a silicon-on-insulator (SOI) wafer and forming a second redistribution layer including a plurality of metal levels, each metal level being included in a respective intermetal dielectric layer on the SOI wafer;
embedding at least one second planarized metal pad in a topmost intermetal dielectric layer on the SOI wafer;
coupling the handle substrate to the SOI wafer;
removing a silicon substrate in the SOI wafer coupled to the handle substrate;
etching, from an exposed surface of a buried oxide layer of the SOI wafer, at least one dielectric-filled deep trench in a space between the first device circuit and the second device circuit;
etching a through substrate via (TSV) from a backside of the SOI wafer though a silicon overlayer and any intervening dielectric layers to access a metal level in the second redistribution layer on the SOI wafer; and
lining the TSV with a conductive material.

31. The method of claim 30, wherein the coupling is a hybrid coupling involving oxide-to-oxide bonding and metal-to-metal coupling.

32. The method of claim 30, wherein the coupling includes placing the SOI wafer on the handle substrate face down with the surfaces of the topmost intermetal dielectric layers on the SOI wafer and the handle substrate in contact with each other, and the at least one first planarized metal pad aligned with and in contact with the at least one second planarized metal pad.

33. The method of claim 30, wherein lining the TSV with a conductive material includes disposing the conductive material in the TSV to connect a first metal level in the second redistribution layer on the SOI wafer to a bond pad formed on a surface of the SOI wafer.
